(19) United States
(12) Patent Application Publication
(10) Pub. No.: US 2026/0247878 A1
(43) Pub. Date: Aug. 20, 2026

(54) HIGH QUALITY GROUP-III METAL NITRIDE CRYSTALS, METHODS OF MAKING, AND METHODS OF USE

(71) Applicants: SLT TECHNOLOGIES, INC, Los Angeles, CA (US); KYOCERA Corporation, Kyoto-shi, Kyoto (JP)

(72) Inventors: Mark P. D'EVELYN, Santa Barbara, CA (US); Takeshi KAMIKAWA, Nara-shi (JP); Yusuke TSUKADA, Vancouver, WA (US)

(21) Appl. No.: 19/472,408

(22) PCT Filed: Apr. 5, 2024
(86) PCT No.: PCT/US2024/023419

§ 371 Date: Oct. 3, 2025

Related U.S. Application Data
(60) Provisional application No. 63/494,658, filed on Apr. 6, 2023.

(51) Int. Cl. H10P 14/20; C30B 29/38; C30B 29/40

(52) U.S. Cl. CPC H10P 14/2926; C30B 29/38; C30B 29/406; H10P 14/2908

(57) ABSTRACT

Embodiments of the disclosure include a free-standing crystal, comprising a group III metal and nitrogen. The free-standing crystal can include a wurtzite crystal structure, a first surface having a maximum dimension greater than 80 millimeters in a first direction, an average concentration of stacking faults below 10³ cm⁻¹, and an average concentration of threading dislocations between 1 cm⁻² and 10⁶ cm⁻², wherein the average concentration of threading dislocations on the first surface varies periodically by at least a factor of two in the first direction, a period of the variation in the first direction being between 5 micrometers and 20 millimeters. Each of five points are distributed evenly within a central 80% of an area of the first surface, the free-standing crystal is characterized by a x-ray rocking curve in the first direction having a full-width-at-half-maximum FWHM±value that is greater than the FWHM±value of an x-ray rocking curve measured in a second direction orthogonal to the first direction by a difference corresponding to a difference in crystallographic orientation between about 0.01 degrees and about 0.4 degrees.

### BACKGROUND OF THE DISCLOSURE

### Field

This disclosure relates generally to techniques for processing materials for manufacture of group-III metal nitride substrates, including gallium-containing nitride substrates. Embodiments of the disclosure include techniques for growing large area substrates using a combination of processing techniques.

### Description of the Related Art

Gallium nitride (GaN) based optoelectronic and electronic devices are of tremendous commercial importance. The quality and reliability of these devices, however, is compromised by high defect levels, particularly threading dislocations, grain boundaries, and strain in semiconductor layers of the devices. Threading dislocations can arise from lattice mismatch of GaN based semiconductor layers to a non-GaN substrate such as sapphire or silicon carbide. Grain boundaries can arise from the coalescence fronts of epitaxially-overgrown layers. Additional defects can arise from thermal expansion mismatch, impurities, and tilt boundaries, depending on the details of the growth of the layers.

The presence of defects has a deleterious effect on epitaxially-grown layers. Such effect includes compromising electronic device performance. To overcome these defects, techniques have been proposed that require complex, tedious fabrication processes to reduce the concentration and/or impact of the defects. While a substantial number of conventional growth methods for gallium nitride crystals have been proposed, limitations still exist. That is, conventional methods still merit improvement to be cost effective and efficient.

Progress has been made in the growth of large-area gallium nitride crystals with considerably lower defect levels than heteroepitaxial GaN layers. However, most techniques for growth of large-area GaN substrates involve GaN deposition on a non-GaN substrate such as sapphire, silicon, or GaAs, which provide the benefit of commercial availability in large diameter sizes at a modest cost. This approach generally gives rise to threading dislocations at average concentrations of 10⁵-10⁷ cm⁻² over the surface of thick boules, as well as significant bow, stress, and strain. In addition, the strain results in a crystallographic radius of curvature of, typically, about 1 to 10 meters and a variation in the crystallographic miscut across the diameter of 50 mm or 100 mm wafers prepared from these boules in the range of 0.1 to 1 degree or more. Reductions in the concentration of threading dislocations and in miscut variation are desirable for a number of applications. Bow, stress, and strain can cause low yields when slicing the boules into wafers, make the wafers susceptible to cracking during down-stream processing, and may also negatively impact device reliability and lifetime. Miscut variation causes variable uptake of various species during the growth of epitaxial layers. For example, variable uptake of indium causes variation in the emission wavelength of LED or laser device structures across a wafer, requiring device makers to measure the output of each individual device and to bin accordingly, raising cost. Miscut variation has also been found to decrease the reliability and lifetime of power devices such as diodes and transistors. A further consequence of bow, stress, and strain is that, during growth in m-plane and semipolar directions, even by near-equilibrium techniques such as ammonothermal growth, significant concentrations of stacking faults may be generated. In addition, the quality of c-plane growth may be unsatisfactory, due to formation of cracks, multiple crystallographic domains, and the like. Capability to manufacture substrates larger than 4 inches is currently very limited, as is the capability to produce large-area GaN substrates with a nonpolar or semipolar crystallographic orientation.

Ammonothermal crystal growth has a number of advantages over hydride vapor phase epitaxy (HVPE) as a means for manufacturing GaN boules. However, the performance of ammonothermal GaN crystal growth processing may be significantly dependent on the size and quality of seed crystals. Seed crystals fabricated by conventional HVPE methods may suffer from both a lattice mismatch with respect to newly-grown ammonothermal material and from many of the limitations described above, and large area ammonothermally-grown crystals are not widely available.

Due to at least the issues described above, there is a need for substrates that have a lower defect density and are formed by techniques that improve the crystal growth process. Also, from the above, it is seen that techniques for improving crystal growth are highly desirable.

### BRIEF SUMMARY OF THE DISCLOSURE

Embodiments of the disclosure generally include methods for processing materials for manufacture of gallium based substrates, more specifically, methods for growing large-area boules or wafers using a combination of processing techniques. Merely by way of example, the disclosure can be applied to growing crystals of GaN, AlN, InN, InGaN, AlGaN, and AlInGaN, and others for manufacture of bulk or patterned substrates. Such bulk or patterned substrates can be used for a variety of applications including optoelectronic devices, lasers, light emitting diodes, solar cells, photo electrochemical water splitting and hydrogen generation, photodetectors, integrated circuits, and transistors, and others.

The methods described herein provide means for fabricating large-area group III metal nitride boules or wafers having reduced defects. The methods described herein thus provide means for fabricating high-performance light emitting diodes and/or laser diodes that avoid potential issues associated with defective regions in the large-area group III metal nitride boules or wafers.

Embodiments of the disclosure may provide a free-standing crystal, comprising a group III metal and nitrogen, wherein the free-standing crystal comprises: a wurtzite crystal structure; a first surface having a maximum dimension greater than 80 millimeters in a first direction; an average concentration of stacking faults below 10³ cm⁻¹; and an average concentration of threading dislocations between 1 cm⁻² and 10⁶ cm⁻². At each of five points distributed evenly within a central 80% of an area of the first surface, the free-standing crystal is characterized by a x-ray rocking curve in the first direction having a full-width-at-half-maximum FWHM_{|}value that is greater than the FWHM₁₉₅ value of an x-ray rocking curve measured in a second direction orthogonal to the first direction by a difference corresponding to a difference in crystallographic orientation between about 0.01 degrees and about 0.4 degrees. In some embodiments, at each of the five points, an x-ray rocking curve in the first direction is characterized by at least two peaks, with a maximum peak separation corresponding to a difference in crystallographic orientation between about 0.01 degrees and about 0.4 degrees. In some embodiments, at each of the five points, an x-ray rocking curve in the first direction is characterized by at least two peaks, with a maximum peak separation corresponding to a difference in crystallographic orientation between about 0.02 degrees and about 0.2 degrees. In some embodiments, at each of the five points, an x-ray rocking curve in the second direction is characterized by a single peak. The first surface of the free-standing crystal may further comprise an impurity concentration of H greater than 10¹⁶ cm⁻³, and an impurity concentration of at least one of Li, Na, K, F, Cl, Br, and I greater than 10¹⁵ cm⁻³, as quantified by calibrated secondary ion mass spectrometry. In some embodiments, the average concentration of threading dislocations on the first surface varies periodically by at least a factor of two in the first direction, a period of the variation in the first direction being between 5 micrometers and 20 millimeters.

Embodiments of the disclosure may provide a method for forming a composite substrate, comprising: forming a pattern on a template, the pattern comprising growth centers having a minimum dimension between 1 micrometer and 100 micrometers, and being characterized by at least one pitch dimension between 20 micrometers and 5 millimeters, wherein the template has a diameter in a first direction of at least 25 millimeters and comprises a group III metal nitride layer on a template substrate comprising one of sapphire, silicon carbide, gallium arsenide, silicon, germanium, a silicon-germanium alloy, MgAl₂O₄ spinel, ZnO, ZrB₂, BP, InP, AlON, ScAlMgO₄, YFeZnO₄, MgO, Fe₂NiO₄, LiGa₅O₈, Na₂MoO₄, Na₂WO₄, In₂CdO₄, lithium aluminate (LiAlO₂), LiGaO₂, Ca₈La₂(PO₄)₆)O₂, gallium nitride (GaN), or aluminum nitride (AlN); growing a group III metal nitride layer from the pattern of growth centers vertically and laterally such that a lateral gap remains between adjacent laterally growth regions, the lateral gap having a width between about 1 micrometer and about 1 millimeter; bonding a handle substrate to the group III metal nitride layer, the handle substrate having a coefficient of thermal expansion in the first direction that is within 10% of the coefficient of thermal expansion of the group III metal nitride layer in the first direction, averaged between room temperature and 800 degrees Celsius. In some embodiments, the group III metal nitride layer comprises a group III metal selected from gallium, aluminum, indium, and a combination of any of the foregoing and nitrogen. In some embodiments, the handle substrate is bonded to the group III metal nitride layer by means of at least one bonding layer having a nascent melting point below 500 degrees Celsius, and the method further comprises thermally treating the bonding layer to cause the melting point of the bonding layer to increase to a temperature of above 600 degrees.

### BRIEF DESCRIPTION OF THE DRAWINGS

FIG. 1 is a simplified diagram illustrating a template having a patterned mask layer according to an embodiment of the present disclosure.

FIGS. 2A-2H are simplified diagrams illustrating a method for forming a template having isolated growth centers according to an embodiment of the present disclosure.

FIG. 3 is a simplified diagram illustrating a template having a patterned mask layer with exposed sidewalls according to an embodiment of the present disclosure.

FIGS. 4A-4G are simplified diagrams illustrating top views of arrangements of openings in a patterned mask layer on a template according to an embodiment of the present disclosure.

FIGS. 5A, 5B, 5C, and 5D are simplified diagrams illustrating an epitaxial lateral overgrowth process for forming a laterally-grown group III metal nitride layer according to embodiments of the present disclosure.

FIGS. 6A-6D are simplified diagrams illustrating preparing a handle substrate for bonding to a template with a laterally-grown group III metal nitride layer according to embodiments of the present disclosure.

FIGS. 7A-7E are simplified diagrams illustrating a handle substrate bonded to a template with a laterally-grown group III metal nitride layer according to embodiments of the present disclosure.

FIGS. 8A-8D are simplified diagrams illustrating a composite substrate according to embodiments of the present disclosure.

FIGS. 9A-9D are simplified diagrams illustrating x-ray rocking curve data according to embodiments of the present disclosure.

FIGS. 10A and 10B are simplified diagrams showing formation of a patterned mask on a composite substrate according to embodiments of the present disclosure.

FIGS. 11A-11D are simplified diagrams showing growth of a bulk group III metal nitride layer over a composite substrate according to embodiments of the present disclosure.

FIGS. 12A-12D are simplified diagrams showing formation of a free-standing group III metal nitride boule according to embodiments of the present disclosure.

FIGS. 13A-13C are simplified diagrams showing formation of free-standing group III metal nitride wafers according to embodiments of the present disclosure.

FIGS. 14A and 14B are simplified diagrams showing locations on a free-standing group III metal nitride wafer for characterization by x-ray rocking curve measurements.

To facilitate understanding, identical reference numerals have been used, where possible, to designate identical elements that are common to the figures. It is contemplated that elements and features of one implementation may be beneficially incorporated in other implementations without further recitation.

### DETAILED DESCRIPTION OF THE DISCLOSURE

According to the present disclosure, techniques related to techniques for processing materials for manufacture of group-III metal nitride and gallium based substrates are provided. More specifically, embodiments of the disclosure include techniques for growing large area substrates using a combination of processing techniques. Merely by way of example, the disclosure can be applied to growing crystals of GaN, AlN, InN, InGaN, AlGaN, and AlInGaN, and others for manufacture of bulk or patterned substrates. Such bulk or patterned substrates can be used for a variety of applications including optoelectronic devices, lasers, light emitting diodes, solar cells, photo electrochemical water splitting and hydrogen generation, photodetectors, integrated circuits, and transistors, and others.

Threading dislocations in GaN are known to act as strong non-radiative recombination centers which can severely limit the efficiency of GaN-based LEDs and laser diodes. Non-radiative recombination generates local heating which may lead to faster device degradation (Cao et al., Microelectronics Reliability, 2003, Vol. 43, pp. 1987-1991). In high-power applications, GaN-based devices suffer from decreased efficiency with increasing current density, known as droop. There is evidence suggesting a correlation between dislocation density and the magnitude of droop in LEDs (Schubert et al., Applied Physics Letters, 2007, Vol. 91, p. 231114). For GaN-based laser diodes there is a well-documented negative correlation between dislocation density and mean time to failure (MTTF) (Tomiya et al., IEEE Journal of Selected Topics in Quantum Electronics, 2004, Vol. 10, No. 6, pp. 1277-1286), which appears to be due to impurity diffusion along the dislocations (Orita et al., IEEE International Reliability Physics Symposium Proceedings, 2009, pp. 736-740). For electronic devices, dislocations have been shown to markedly increase the leakage current (Kaun et al., Applied Physics Express, 2011, Vol. 4, p. 024101) and reduce the device lifetime (Tapajna et al., Applied Physics Letters, 2011, Vol. 99, pp. 223501-223503) in HEMT structures. One of the primary advantages of using bulk GaN as a substrate material for epitaxial thin film growth is a large reduction in the concentration of threading dislocations in the film. Therefore, the dislocation density in the bulk GaN substrate will have a significant impact on the device efficiency and the reliability.

As noted above, lateral epitaxial overgrowth (LEO) is a method that has been widely applied to improvement in the crystallographic quality of films grown by vapor-phase methods. For example, methods have been reported whereby GaN layers were nucleated on a sapphire substrate, a SiO₂ mask with a periodic array of openings was deposited on the GaN layer, and then GaN was grown by metalorganic chemical vapor deposition (MOCVD) through the openings in the SiO₂ mask layer, grew laterally over the mask, and coalesced. The dislocation density in the areas above the openings in the mask were very high, similar to the layer below the mask, but the dislocation density in the laterally-overgrown regions was orders of magnitude less. This method is attractive because it can be applied to large area substrates, significantly reducing their dislocation density. Similar methods, with variations, have been applied by a number of groups to vapor-phase growth of GaN layers. These methods are variously referred to as LEO, epitaxial lateral overgrowth (ELO or ELOG), selective area growth (SAG), and dislocation elimination by epitaxial growth with inverse pyramidal pits (DEEP), or the like. In the case of essentially all variations of this method, it is believed that a thin heteroepitaxial GaN layer is grown on a non-GaN substrate, a patterned mask is deposited on the GaN layer, and growth is re-initiated in a one-dimensional or two-dimensional array of openings in the mask. The period or pitch of the growth locations defined by the openings in the mask is typically between 2 and 400 micrometers, most typically between about 5 and 100 micrometers. The individual GaN crystallites or regions grow and then coalesce. Epitaxial growth may then be continued on top of the coalesced GaN material to produce a thick film or “ingot.” A relatively thick GaN layer may be deposited on the coalesced GaN material by HVPE. The LEO process is capable of large reductions in the concentration of dislocations, particularly in the regions above the mask, typically to levels of about 10⁵-10⁷ cm⁻². However, the laterally-grown wings of the formed LEO layer may be crystallographically tilted from the underlying substrate (“wing tilt”), by as much as several degrees, which may be acceptable for a thin-film process but may not be acceptable for a bulk crystal growth process, as it may give rise to stresses and cracking as well as unacceptable variation in surface crystallographic orientation.

Typically, laterally-grown wings are caused to coalesce, which may have the undesirable consequence of generating new stresses, particularly when the substrate is a dissimilar material having a different thermal expansion coefficient, as well as a line of dislocations at the coalescence front. In some cases, stacking faults are also generated at or near coalescence fronts. Kamikawa and co-workers, [for example, Optics Express 27, 24717 (2019); Cryst. Growth Design 23, 4855 (2023); EP3619748A1; EP3939070A1; JP2022104771A; JP2022104770A] have disclosed variations of the LEO method, where wing growth is terminated before coalescence, maintaining low dislocation densities throughout the wings and enabling device-layer transfer, for example, for applications such as lasers or micro LEDs.

The focus of the current disclosure is to take advantage of the high material quality, low stress, and large-area substrate capability of the non-coalesced LEO method to fabricate a large area, free-standing, high quality seed crystal suitable for ammonothermal crystal growth or bulk crystal growth by another method. In certain embodiments, the polarity of the seed crystal is reversed from that employed during the initial non-coalesced LEO growth.

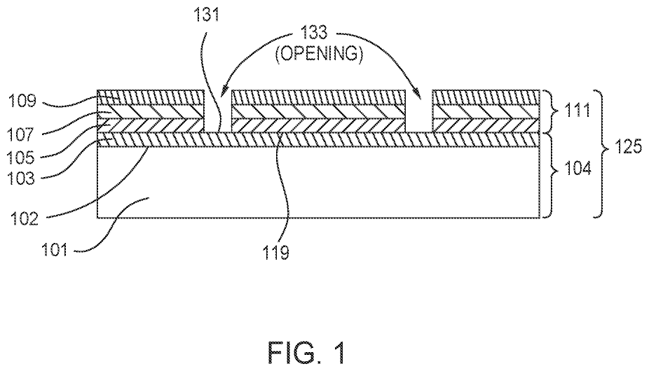

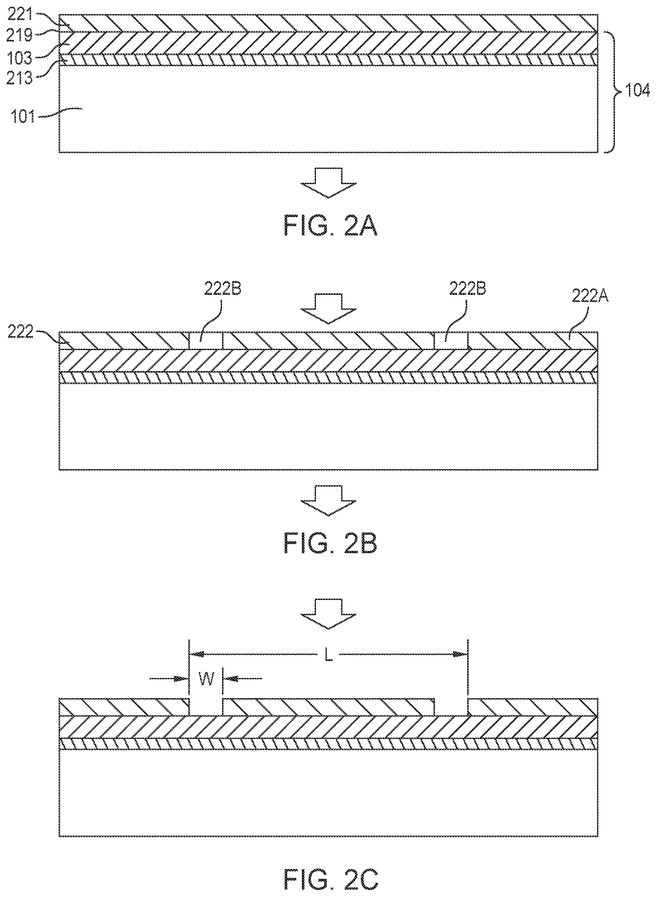

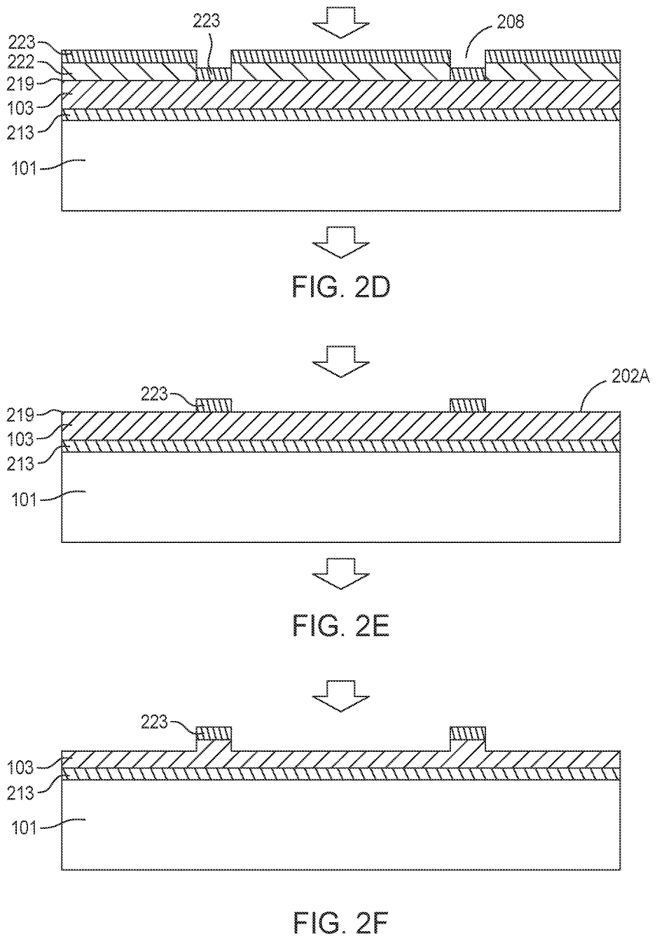

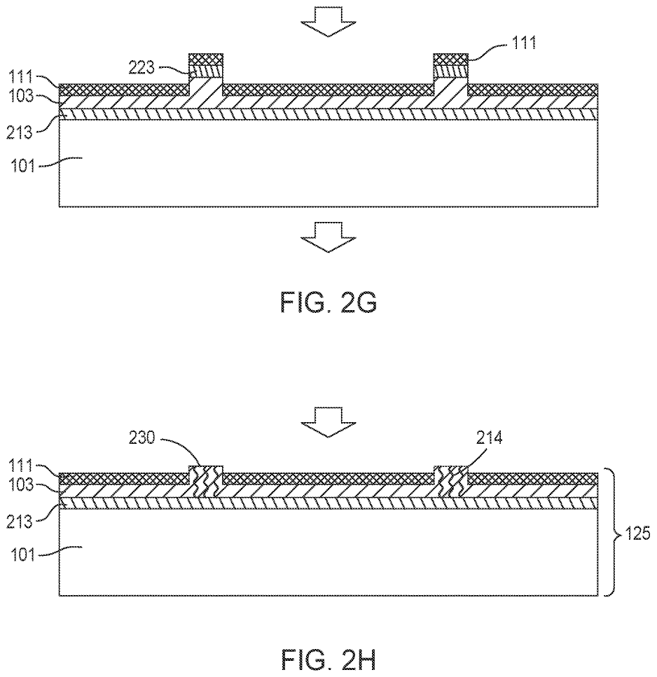

FIG. 1 is a schematic diagram showing a patterned mask on a substrate, formed according to methods that are known in the art. Referring to FIG. 1 and also to FIG. 2A, a template substrate 101 is provided. Template substrate 101 preferably consists of or includes a substrate material that is a single crystal. The template substrate 101 can be a commercially available large diameter substrate that consists of or includes a material, such as sapphire (Al₂O₃), silicon carbide (SiC), or silicon. In alternative embodiments, template substrate 101 may consist of or include gallium arsenide, germanium, a silicon-germanium alloy, MgAl₂O₄ spinel, ZnO, ZrB₂, BP, InP, AlON, ScAlMgO₄, YFeZnO₄, MgO, FezNiO₄, LiGa₅O₈, Na₂MoO₄, Na₂WO₄, In₂CdO₄, lithium aluminate (LiAlO₂), LiGaO₂, Ca₈La₂(PO₄)₆O₂, gallium nitride (GaN), aluminum nitride (AlN), or the like. One or both of the large-area surfaces of template substrate 101 may be polished and/or chemical-mechanically polished. In certain embodiments, template substrate 101 consists of or includes sapphire and has a large-area surface 102 that has a crystallographic orientation within 5 degrees, within 2 degrees, within 1 degree, or within 0.5 degree of (0001), (10-10), (10-12), (22-43), or (11-23). In certain embodiments, template substrate 101 consists of or includes sapphire and has a large-area surface 102 that is misoriented from (0001) by an angle between about 0.5 degree and about 8 degrees, or between about 2 degrees and about 4 degrees, toward the {11-20} a-plane, toward the {10-10} m-plane, or toward a-plane intermediate between a-plane and m-plane. In certain embodiments, template substrate 101 has a cubic structure and large-area surface 102 has a crystallographic orientation within 5 degrees, within 2 degrees, within 1 degree, or within 0.5 degree of {111}, {100}, {110}, or {114}. Other orientations may also be chosen. In a specific embodiment, template substrate 101 consists essentially of single-crystal silicon. Large-area surface 102 may have a maximum lateral dimension between about 5 millimeters and about 600 millimeters and a minimum lateral dimension between about 1 millimeter and about 600 millimeters and template substrate 101 may have a thickness between about 10 micrometers and about 10 millimeters, or between about 100 micrometers and about 2 millimeters. In certain embodiments, template substrate 101 is substantially circular, with one or more orientation flats. In alternative embodiments, template substrate 101 is substantially rectangular. In certain embodiments, large-area surface 102 has a maximum dimension of about 50 mm, 100 mm, 125 mm, 150 mm, 200 mm, 250 mm, or 300 mm. The variation in the crystallographic orientation of the large-area surface 102 may be less than about 5 degrees, less than about 2 degrees, less than about 1 degree, less than about 0.5 degree, less than about 0.2 degree, less than about 0.1 degree, or less than about 0.05 degree.

Template substrate 101 may have a surface threading dislocation density less than about 10⁷ cm⁻², less than about 10⁶ cm⁻², less than about 10⁵ cm⁻², less than about 10⁴ cm⁻², less than about 10³ cm⁻², or less than about 10² cm⁻². Template substrate 101 may have a stacking-fault concentration below about 10⁴ cm⁻¹, below about 10³ cm⁻¹, below about 10² cm⁻¹, below about 10 cm⁻¹ or below about 1 cm⁻¹. Template substrate 101 may have a symmetric x-ray rocking curve full width at half maximum (FWHM) less than about 500 arcsec, less than about 300 arcsec, less than about 200 arcsec, less than about 100 arcsec, less than about 50 arcsec, less than about 35 arcsec, less than about 25 arcsec, or less than about 15 arcsec. Template substrate 101 may have a crystallographic radius of curvature greater than 10 meters, greater than 100 meters, or greater than 1000 meters, in at least one, at least two, or in three independent or orthogonal directions. In certain embodiments, template substrate 101 is patterned, with certain regions comprising (0001)-oriented facets exposed and other regions masked.

In certain embodiments, a group III metal nitride layer 103 is bonded to or formed on a surface 102 of the template substrate 101. Group III metal nitride layer 103 may include gallium and, together with template substrate 101, will hereinafter be referred to as template 104. Group III metal nitride layer 103 may be deposited by HVPE, by metalorganic chemical vapor deposition (MOCVD), molecular beam epitaxy (MBE), or the like. Group III metal nitride layer 103 may have a thickness between about 1 micrometer and about 100 micrometers, between about 1 micrometer and about 10 micrometers, or between about 1 micrometer and about 3 micrometers. In certain embodiments, group III metal nitride layer is grown by MOCVD using a gallium source, such as trimethyl gallium, in ammonia and a carrier gas such as N₂ or H₂. The substrate temperature during MOCVD growth may be between about 980 degrees Celsius and about 1080 degrees Celsius, the pressure may be between about 30 kilopascals and about 120 kilopascals, and the V/III ratio may be between about 2000 and about 10000 or between about 3000 and about 5000. In certain embodiments, group III metal nitride layer 103 has a wurtzite crystal structure and a crystallographic orientation within 5 degrees, within 2 degrees, within 1 degree, or within 0.5 degree of (0001)+c-plane, (000-1) −c-plane, {10-10} m-plane, {11-2±2}, {60-6±1}, {50-5±1}, {40-4±1}, {30-3±1}, {50-5±2}, {70-7±3}, {20-2±1}, {30-3±2}, {40-4±3}, {50-5±4}, {10-1±1}, {10-1±2}, {10-1±3}, {21-3±1}, or {3 0 −3±4}. It will be understood that plane {3 0 −3±4} means the {3 0 −3 4} plane and the {3 0 −3 −4} plane. In certain embodiments, a nucleation layer (not shown) is present at the interface between template substrate 101 and group III metal nitride layer 103. In certain embodiments, the nucleation layer consists of or includes one or more of aluminum nitride, gallium nitride, and zinc oxide. In certain embodiments, the nucleation layer is deposited on template substrate 101 by at least one of low-temperature MOCVD, sputtering, and electron-beam evaporation. In certain embodiments, the nucleation layer has a thickness between about 1 nanometer and about 200 nanometers or between about 50 nanometers and about 150 nanometers. In certain embodiments, a stress-management layer 213 is deposited overlying the nucleation layer and underlying group III metal layer 103 (FIG. 2A). In certain embodiments, the stress management layer comprises AlₓGa₁₋ₓN, where 0<x<1, is deposited by MOCVD, and has a thickness between about 0.5 micrometer and about 4 micrometers or between about 1 micrometer and about 2 micrometers.

In certain embodiments, a patterned mask layer 111 is applied to surface 119 of template 104, forming patterned composite substrate 125, as shown schematically in FIG. 1. The patterned mask layer 111 may comprise an inert layer 109 and, optionally, one or more of an adhesion layer 105 that is disposed on template surface 119 and a diffusion barrier layer 107 disposed between the adhesion layer and the inert layer. In one embodiment, prior to applying the patterned mask layer 111 a patterned resist layer (not shown) is formed on the exposed surface 119 of template 104 by conventional lithography techniques. Then one or more of adhesion layer 105, diffusion-barrier layer 107, and inert layer 109 may be deposited over the patterned photoresist layer, which is then followed by lift-off process that removes the patterned photoresist and portions of mask layer 111 that overlie the patterned photoresist material and thus forms the structure illustrated in FIG. 1 in which portions 131 of the surface 119, on which the patterned resist was positioned, are exposed through openings 133. Adhesion layer 105, if present, may consist of or include one or more of Ti, TiN, TiN_{y}, TiSi₂, Ta, TaN_{y}, Al, Ge, AlₓGe_{y}, Cu, Si, Cr, V, Ni, W, TiWₓ, TiWₓN_{y}, or the like and may have a thickness between about 1 nanometer and about 1 micrometer. Diffusion-barrier layer 107, if present, may consist of or include one or more of TiN, TiN_{y}, TiSi₂, W, TiWₓ, TiN_{y}, WN_{y}, TaN_{y}, TiWₓN_{y}, TiWₓSi_{z}N_{y}, TiC, TiCN, Pd, Rh, Cr, or the like, and have a thickness between about 1 nanometer and about 10 micrometers. Inert layer 109 may consist of or include one or more of SiO2, SiNₓ, WSiNₓ, TiN, Au, Ag, Pt, Pd, Rh, Ru, Ir, Ni, Cr, V, Ti, or Ta and may have a thickness between about 10 nanometers and about 100 micrometers. The one or more mask layers may be deposited by sputter deposition, thermal evaporation, electron-beam evaporation, or the like. In certain embodiments, a relatively thin portion of inert layer 109, for example, 10 to 500 nanometers thick, is deposited prior to the lift-off process. After performing the lift-off process, an additional, thicker portion of inert layer 109, for example, 5 to 100 micrometers thick, may be deposited over the already-patterned relatively thin portion of inert layer 109 by electroplating, electroless deposition, or the like. Openings 133 in the mask layer 111 may constitute growth centers during a subsequent growth step (see below).

Other methods besides the lift-off procedure described above may be used to form the patterned mask layer 111, including shadow masking, positive resist reactive ion etching, wet chemical etching, ion milling, laser ablation, and nanoimprint lithography, plus variations of the negative resist lift-off procedure described above. In certain embodiments, a blanket mask layer is deposited over template surface 119, which is then patterned by means of a lithography process that is then followed by wet or dry etching process or by means of laser ablation.

In certain embodiments, a process sequence, as shown in FIGS. 2A-2H, is performed such that portions of group III metal nitride layer 103 are removed to form mesas or isolated growth centers 230 (FIG. 2H). Referring to FIG. 2A, a photoresist layer 221 may first be deposited on surface 219 of the composite substrate 104 by methods that are known in the art. For example, in a certain embodiment, a liquid solution of a negative photoresist is first applied to surface 219. Composite substrate 104 is then spun at a high speed (for example, between 1000 to 6000 revolutions per minute for 30 to 60 seconds), resulting in a uniform photoresist layer 221 on surface 219. Photoresist layer 221 may then be baked (for example, between about 90 and about 120 degrees Celsius) to remove excess photoresist solvent. After baking, the photoresist layer 221 may then be exposed to UV light through a photomask to form a patterned photoresist layer 222 (FIG. 2B) having a pre-determined pattern of cross-linked photoresist, such as cross-linked regions 222A and opening regions 222B. The patterned photoresist layer 222 may consist of or include stripes, dots, or other shapes having characteristic width or diameter W and pitch L. Patterned photoresist layer 222 may then be developed to remove non-cross-linked material, as shown in FIG. 2C.

Referring to FIGS. 2D-2E , one or more dry-etch mask layers 223 may be deposited overlying surface 219, and thus the one or more dry-etch mask layers 223 are formed within openings 208 and on patterned photoresist layer 222. Dry-etch mask layer 223 may consist of or include Ni, Ti, Cr, Al, SiO₂, SiNₓ, or the like and may have a thickness between about 10 nanometers and about 100 micrometers. The one or more dry-etch mask layers 223 may be deposited by plasma-enhanced chemical vapor deposition, sputter deposition, thermal evaporation, electron-beam evaporation, or the like. After deposition of the one or more dry-etch masking layer(s) 223, the patterned portions of the one or more dry-etch layer(s) 223 residing above the patterned photoresist layer 222 is then lifted off along with the photoresist layer 221 by methods that are known in the art. Unmasked regions 202A of surface 219 may then be dry-etched, for example, by reactive ion etching or by means of an inductively-coupled plasma, using one or more of CF₄, NF₃, Cl₂, BCl₃, SiCl₄, or CH₂Cl₂ as a reagent gas to remove portions of the group III metal nitride layer 103 in the unmasked regions 202A of surface 219, as shown schematically in FIG. 2F. The etch depth may be between about 10% and about 90%, or between about 20% and about 80% of the original thickness of group III metal nitride layer 103.

Referring to FIG. 2G, a patterned mask layer 111 may then be deposited, as described above. Portions of patterned mask layer 111 overlying dry-etch mask layer 223, along with the remaining portions of the dry-etch mask layer 223 are then removed, for example, by wet etching, to expose the formed mesas or isolated growth centers 230 on patterned seed crystal 125, as shown in FIG. 2H. Threading dislocations 214, originating from one or more of the nucleation layer, the stress relaxation layer 213 or initial growth of group III metal nitride layer 103, may propagate to the surfaces of isolated growth centers 230.

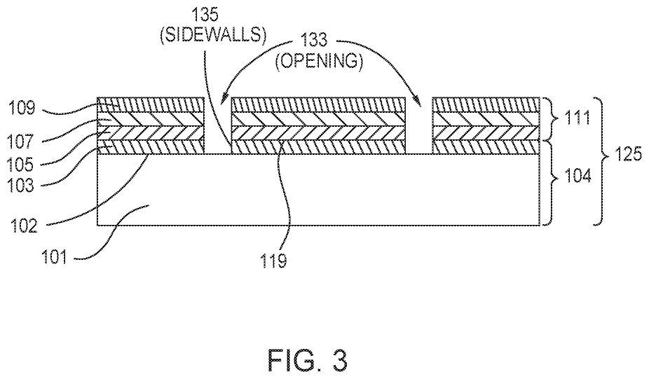

FIG. 3 illustrates an alternative embodiment, where openings 133 in mask 111 are extended through group III metal nitride layer 103, exposing sidewalls 135. For example, referring again to FIG. 1, the exposed portions of surface 131 of group III metal nitride layer 103, with patterned mask layer 111 disposed thereon, may be removed, for example, by one or more of wet etching, dry etching, and laser ablation, exposing sidewalls 135 in patterned seed crystal 125.

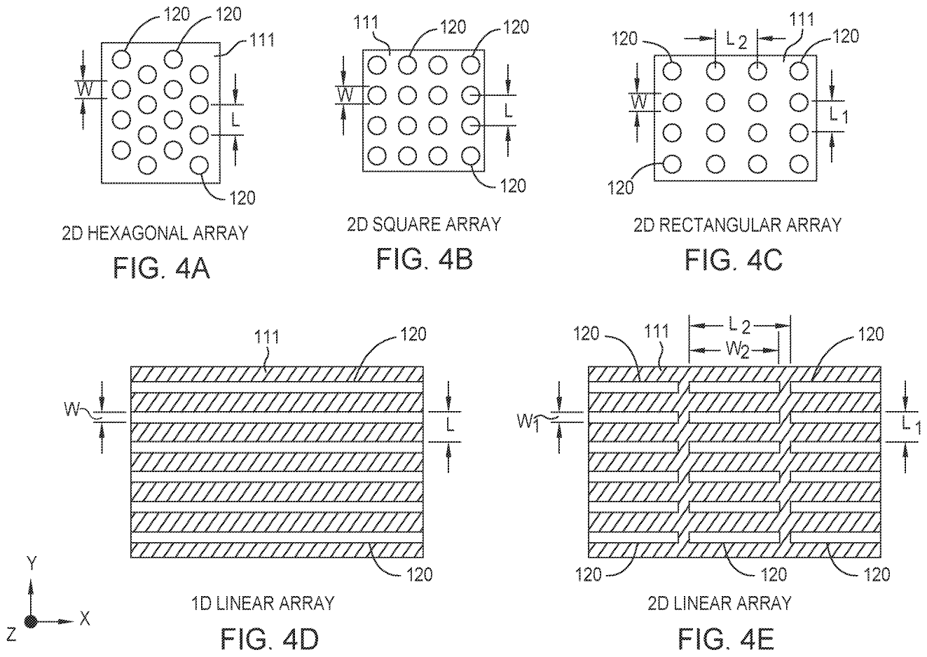

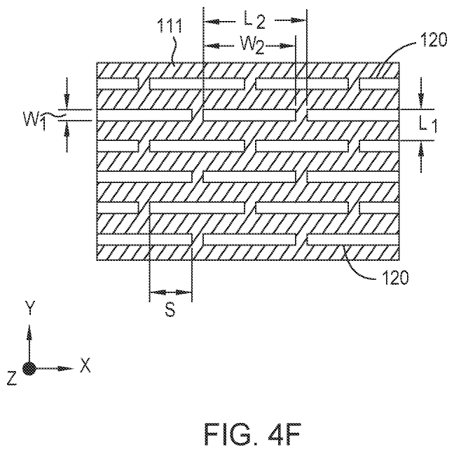

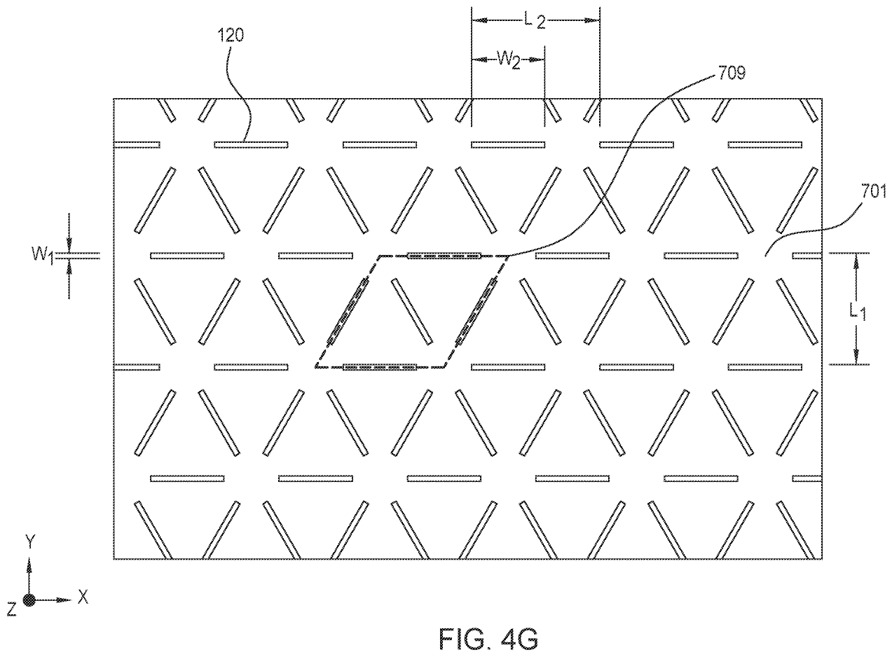

FIGS. 4A-4G illustrate top views of arrangements of exposed regions 120 on the substrate 101 formed by one or more of the processes described above. The exposed regions 120 (or also referred to herein as growth centers), which are illustrated, for example, in FIGS. 4A-4G, may include exposed portions 131 of group III metal nitride layer 103 with openings 133 formed in patterned mask layer 111 shown in FIG. 1, isolated growth centers 230 shown in FIG. 2H, or sidewalls 135 of group III metal nitride layer 103 with openings 133 formed in patterned mask layer 111 shown in FIG. 3. In certain embodiments, the exposed regions 120 are arranged in a one-dimensional (1D) array in the y-direction, such as a single column of exposed regions 120 as shown in FIG. 4D. In certain embodiments, the exposed regions 120 are arranged in a two-dimensional (2D) array in x-and y-directions, such as illustrated in FIGS. 4A-4C and 4E-4G. The exposed regions 120 may be round, square, rectangular, triangular, hexagonal, or the like, and may have an opening dimension or diameter W between about 1 micrometer and about 5 millimeters, between about 2 micrometers and about 500 micrometers, or between about 5 micrometers and about 50 micrometers, such as illustrated in FIGS. 4A-4C. The exposed regions 120 may be arranged in a 2D hexagonal or square array with a pitch dimension L between about 5 micrometers and about 20 millimeters or between about 200 micrometers and about 5 millimeters, or between about 500 micrometers and about 2 millimeters, such as illustrated in FIGS. 4A-4C. The exposed regions 120 may be arranged in a 2D array, in which the pitch dimension L₁ in the y-direction and pitch dimension L₂ in the x-direction may be different from one another, as illustrated in FIGS. 4C, 4E-4G. The exposed regions 120 may be arranged in a rectangular, parallelogram, hexagonal, or trapezoidal array (not shown), in which the pitch dimensions L₁ in the y-direction and L₂ in the x-direction may be different from one another. The array of exposed regions 120 may also be linear or irregular shaped. The exposed regions 120 may be placed in registry with the crystal structure of substrate 101. For example, in certain embodiments, surface 119 of template 104 has a hexagonal, e.g., a (0001) or (000-1) crystallographic orientation, and the exposed regions 120 comprise a 2D hexagonal array such that the separations between nearest-neighbor exposed regions 120 are parallel to <11-20> or <10-10> directions in large-area surface 102 of the substrate 101. In certain embodiments, surface 119 of template 104 is nonpolar or semipolar and the exposed regions 120 comprise a 2D square or rectangular array such that the separations between nearest-neighbor openings are parallel to the projections of two of the c-axis, an m-axis, and an a-axis on large-area surface 102 of substrate 101. In certain embodiments, the pattern of exposed regions 120 is obliquely oriented with respect to the structure of surface 119, for example, wherein the exposed regions 120 are rotated by between about 1 degree and about 44 degrees with respect to a high-symmetry axis of the group III metal nitride layer 103, such as a projection of the c-axis, an m-axis, or an a-axis on surface 119 of template 104. In certain embodiments, the exposed regions 120 are substantially linear rather than substantially round. In certain embodiments, the exposed regions 120 are slits having a width W and period L that run across the entire length of substrate 101, as illustrated in FIG. 4D. In certain embodiments, the exposed regions 120 are slits that have a width W₁ in the y-direction and a predetermined length W₂ in the x-direction that is less than the length of substrate 101, and may be arranged in a 2D linear array with period L₁ in the y-direction and period L₂ in the x-direction, as illustrated in FIGS. 4E-4G. In some embodiments, adjacent rows of exposed regions 120 (e.g., slits) may be offset in the x-direction from one another rather than arranged directly adjacent, as shown in FIG. 4F. In certain embodiments, the adjacent rows of exposed regions 120 (e.g., slits) may be offset in the longitudinal y-direction from one another. In other embodiments, as shown in FIG. 4G, the exposed regions 120 include slits that extend in directions that are rotated from one another by 60 degrees, 90 degrees, or a multiple thereof.

One or more patterned substrates 125 may then be placed in a growth reactor and a group III metal nitride film grown over the masked layer. The growth may be performed by metalorganic chemical vapor deposition (MOCVD), hydride vapor phase epitaxy (HVPE), molecular beam epitaxy (MBE), ammonothermal growth, flux growth, or the like, according to methods that are known in the art.

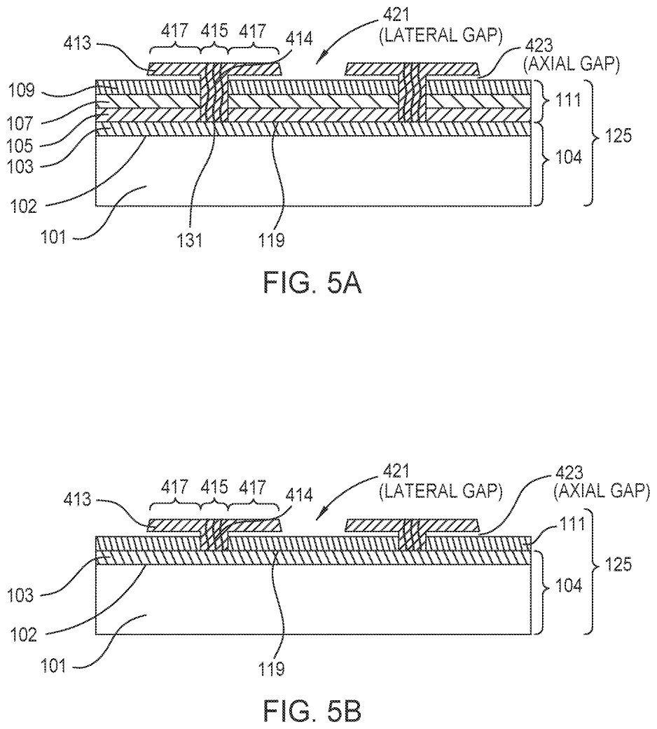

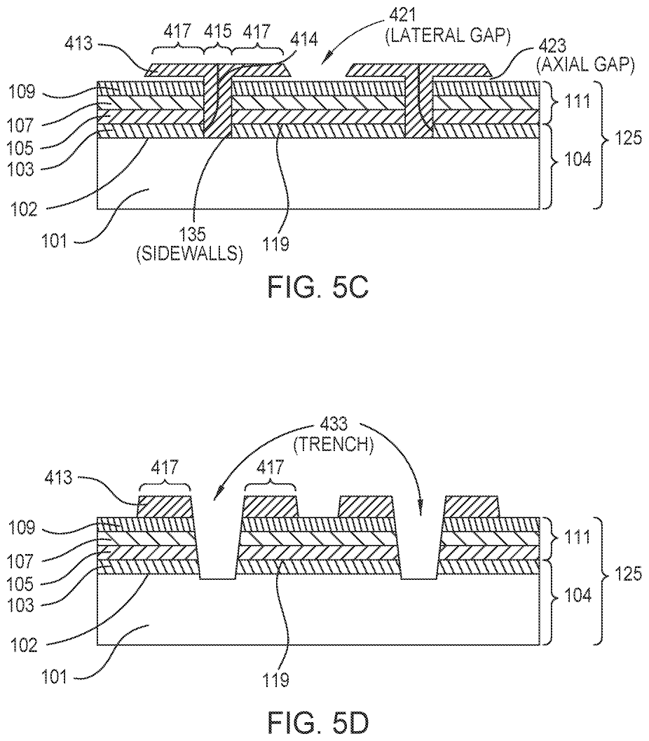

FIGS. 5A, 5B, and 5C are simplified diagrams illustrating epitaxial lateral overgrowth processes on patterned seed crystals as illustrated in FIGS. 1, 2H, and 3, respectively. Referring to FIGS. 1 and 5A, a group III metal nitride layer 413 grows through the openings 133 of patterned mask layer 111 and then grows laterally over patterned mask layer 111. Group III metal nitride layer 413 includes window regions 415, which have grown vertically with respect to the openings 133 (FIG. 1) in patterned mask layer 111 and wing regions 417, which have grown laterally over patterned mask layer 111. Threading dislocations 414 may be present in window regions 215, originating from threading dislocations that were present at the surface of the group III metal nitride layer 103. In certain embodiments, the epitaxial growth process is performed by MOCVD, initially under a first condition that favors vertical growth, for example, an initial substrate temperature between about 980 degrees Celsius and about 1080 degrees Celsius, a pressure between about 30 kilopascals and about 120 kilopascals, and a V/III ratio between about 2000 and about 10000 or between about 3000 and about 5000. The growth condition may then be changed to a second condition that favors lateral growth, for example, by one or more of raising the substrate temperature by an additional between about 75 degrees Celsius and about 125 degrees Celsius, increasing the V/III ratio by between 50% and about 500%, or decreasing the pressure to value between 20% and 90% of the first-condition pressure. The epitaxial overgrowth process is typically terminated before adjacent wing regions 417 coalesce, leaving lateral gaps 421 between them. Lateral gaps 421 may have a width between about 1 micrometer and about 1 millimeter, between about 3 micrometers and about 500 micrometers, or between about 10 micrometers and about 250 micrometers. In certain embodiments, lateral gaps 421 are zero, that is, adjacent wing regions 417 are allowed to coalesce.

Referring to FIGS. 2H and 5B, a group III metal nitride layer 413 grows laterally from isolated growth centers 230 over patterned mask layer 111. Group III metal nitride layer 413 includes window regions 415, which have grown vertically with respect to the openings 133 in patterned mask layer 111 and wing regions 417, which have grown laterally over patterned mask layer 111. Threading dislocations 414 may be present in window regions 215, originating from threading dislocations that were present at the surface of the group III metal nitride layer 103. The epitaxial overgrowth process is typically terminated before adjacent wing regions 417 coalesce, leaving lateral gaps 421 between them. In certain embodiments, lateral gaps 421 are zero, that is, adjacent wing regions 417 are allowed to coalesce. Axial gaps 423, between patterned mask layer 111 and wing regions 417, may be between about 0.1 micrometer and about 10 micrometers, between about 0.5 micrometer and about 7 micrometers, or between about 1 micrometer and about 5 micrometers. In certain embodiments, group III metal nitride layer 413 is grown by MOCVD, initially using a first condition that favors vertical growth, followed by a second condition that favors lateral growth, as described above.

Referring to FIGS. 3 and 5C, a group III metal nitride layer 413 grows laterally from sidewalls 135, grows vertically through the openings 133 of patterned mask layer 111, and then grows laterally over patterned mask layer 111. Group III metal nitride layer 413 comprises window regions 415, which have grown vertically with respect to the openings 133 in patterned mask layer 111 and wing regions 417, which have grown laterally over patterned mask layer 111. Some threading dislocations 414 may be present in window regions 215, originating from threading dislocations from sidewall 135 that bent during the growth process. Typically, the concentration of threading dislocations 414 in window region 415 from a sidewall lateral epitaxial growth process will be lower than the concentration of threading dislocations 414 from a standard lateral epitaxial overgrowth process. Typically, the epitaxial overgrowth process is terminated before adjacent wing regions 417 coalesce, leaving lateral gaps 421 between them. Lateral gaps 421 may have a width between about 1 micrometer and about 1 millimeter, between about 3 micrometers and about 500 micrometers, or between about 10 micrometers and about 250 micrometers. In certain embodiments, lateral gaps 421 are zero, that is, adjacent wing regions 417 are allowed to coalesce.

Referring to FIG. 5D, in certain embodiments, trenches 433 are formed, for example, by lithography and dry etching processes, in order to remove window regions 415 (FIG. 5C), which may have elevated concentrations of threading dislocations, by comparison to wing regions 417.

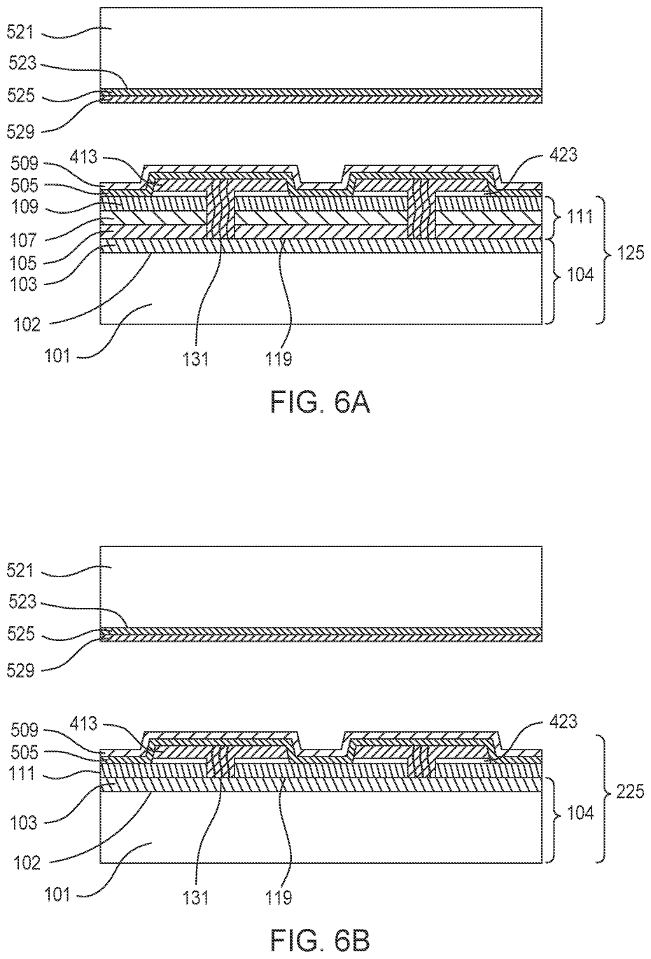

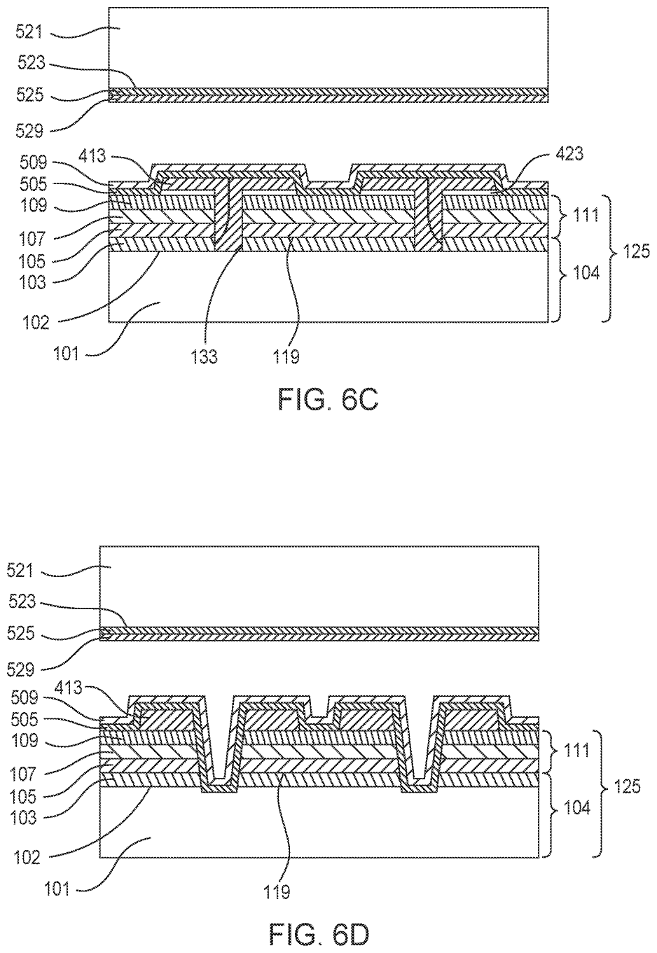

Referring to FIG. 6A-6D, an epilayer adhesion layer 505 may be deposited overlying patterned group III metal nitride layer 413, as shown schematically in FIGS. 5A-5D, respectively, and an epilayer bonding layer 509 may be deposited overlying epilayer adhesion layer 505, if the latter is present, and overlying patterned group III metal nitride layer 413.

Referring again to FIGS. 6A-6D, a handle substrate 521 having surface 523 may be provided. Surface 523 may have a maximum lateral dimension between about 5 millimeters and about 600 millimeters and a minimum lateral dimension between about 1 millimeter and about 600 millimeters and handle substrate 521 may have a thickness between about 10 micrometers and about 10 millimeters, or between about 100 micrometers and about 2 millimeters. In certain embodiments, handle substrate 521 is substantially circular, with one or more orientation flats. In alternative embodiments, handle substrate 521 is substantially rectangular. In certain embodiments, surface 523 has a maximum dimension of about 50 mm, 100 mm, 125 mm, 150 mm, 200 mm, 250 mm, or 300 mm. Handle substrate 521 may consist of or include a substrate material that is a single crystal, polycrystalline or amorphous material. Handle substrate 521 may be characterized by a coefficient of thermal expansion (CTE) in a direction parallel to surface 523 that is within 10%, within 5%, with 2%, or within 1% of the CTE of group III metal nitride layer 413 in a direction parallel to surface 102, averaged over a temperature between room temperature and 800 degrees Celsius. In certain embodiments, handle substrate 521 includes or consists of polycrystalline group III metal nitride, molybdenum, a molybdenum-tungsten alloy, or single-crystal group III metal nitride. Handle substrate 521 may consist of or include substantially the same composition as group III metal nitride layer 413. In certain embodiments, handle substrate 521 consists of or includes crystallographically-textured or highly-crystallographically-textured polycrystalline group III metal nitride. In certain embodiments, handle substrate 521 is characterized by an x-ray diffraction pole figure having a (0002) reflection at an angle within 10 degrees, within 5 degrees, within 2 degrees, or within 1 degree of a normal to its surface and where the full-width-at-half-maximum (FWHM) of the (0002) reflection in a χ- (or α-)scan is less than or equal to 20 degrees, less than or equal to 10 degrees, less than or equal to 5 degrees, or less than or equal to 3 degrees. Since the CTE of GaN differs by approximately 12% between the a and c directions, for example, polycrystalline GaN will not have a precise CTE match to a single-crystal GaN layer. However, the mismatch is small and the temperature dependence of the CTE in the a and c directions are similar. In addition, in the limit that the polycrystalline GaN material is highly crystallographically-textured in the c-direction, its CTE in the lateral direction will closely approximate the CTE of single-crystal GaN in the a-direction. Exemplary methods for fabricating textured, polycrystalline group III metal nitride are described in U.S. Pat. Nos. 8,039,412 and 10,094,017, each of which is incorporated by reference in its entirety. In one specific embodiment, handle substrate 521 consists of or includes oxygen-doped aluminum nitride.

Referring again to FIGS. 6A-6D, a handle bonding layer 529 may be deposited overlying an optional handle adhesion layer 525, which in turn overlies surface 523 of handle substrate 521. Handle adhesion layer 525 and epilayer adhesion layer 505 may comprise at least one of Ti and Cr and may have a thickness between about 1 nanometer and about 10 nanometers. Handle bonding layer 529 and epilayer bonding layer 509 may include or consist of at least one of SiO₂, GeO₂, SiNₓ, AlNₓ, or B, Al, Si, P, Zn, Ga, Si, Ge, Au, Ag, Ni, Ti, Cr, Zn, Cd, In, Sn, Sb, Tl, W, In, Cu, or Pb, or an oxide, nitride, or oxynitride thereof. Handle bonding layer 529 and epilayer bonding layer 509 may further comprise hydrogen. In a specific embodiment, at least one of handle bonding layer 529 and epilayer bonding layer 509 includes or consists of at least one of Au and Ag. Handle bonding layer 529, epilayer bonding layer 509, and optional epilayer adhesion layer 505 and handle adhesion layer 525, may be deposited by thermal evaporation, electron-beam evaporation, sputtering, chemical vapor deposition, plasma-enhanced chemical vapor deposition, electroplating, or the like, or by thermal oxidation of a deposited metallic film. The thickness of handle bonding layer 529 may be, for example, between about 1 nanometer and about 10 microns, or between about 10 nanometers and about 1 micron. At least one of the handle bonding layer 529 and the epilayer bonding layer 509 may be annealed, for example, to a temperature between about 300 degrees Celsius and about 1,000 degrees Celsius. In some embodiments, at least one of the handle bonding layer 529 and the epilayer bonding layer 509 is chemical-mechanically polished. In a particular embodiment, the root-mean-square surface roughness of at least one of the handle bonding layer 529 and the epilayer bonding layer 509 may be below about 5 nanometers, below about 2 nanometers, below about 1 nanometer, below about 0.5 nanometer, or below about 0.3 nanometer, as measured over a 20×20 μm² area.

Handle bonding layer 529 may comprise a non-homogenous composition. In some embodiments, handle bonding layer 529 comprises a stack of thin films of varying compositions or a film of graded or continuously-varying composition, either vertically or laterally. In some embodiments, handle bonding layer 529 or at least one thin film contained within handle bonding layer 529 is laterally non-uniform in composition. In some embodiments, handle bonding layer 529 or at least one thin film contained within comprises an array of dots, squares, rectangle, lines, a grid pattern, or the like. The composition of epilayer bonding layer 509 or handle bonding layer 529 may be chosen so as to undergo nascent melting at a temperature below about 300 degrees Celsius, below about 400 degrees Celsius, or below about 500 degrees Celsius. The composition of handle bonding layer 529 may be chosen so as to have a melting point above about 600 degrees Celsius, above about 700 degrees Celsius, above about 800 degrees Celsius, or above about 900 degrees Celsius, so as to remain solid during subsequent processing. The composition and structure of handle bonding layer 529 may be chosen so as to undergo nascent melting at a temperature below about 300 degrees Celsius, below about 400 degrees Celsius, below about 500 degrees Celsius, or below about 600 degrees Celsius, then, following a thermal treatment at a temperature below the solidus temperature, to remain unmelted, or with a volume fraction of melt below about 20%, below about 10%, or below about 5%, at a temperature above about 600 degrees Celsius, above about 700 degrees Celsius, above about 800 degrees Celsius, or above about 900 degrees Celsius. In a specific embodiment, at least one of handle bonding layer 529 and epilayer bonding layer 509 includes at least one of Au and Ag plus an additional component that forms a low-melting eutectic with at least one of Au or Ag. In a specific embodiment, the additional component includes at least one of Sn and Si.

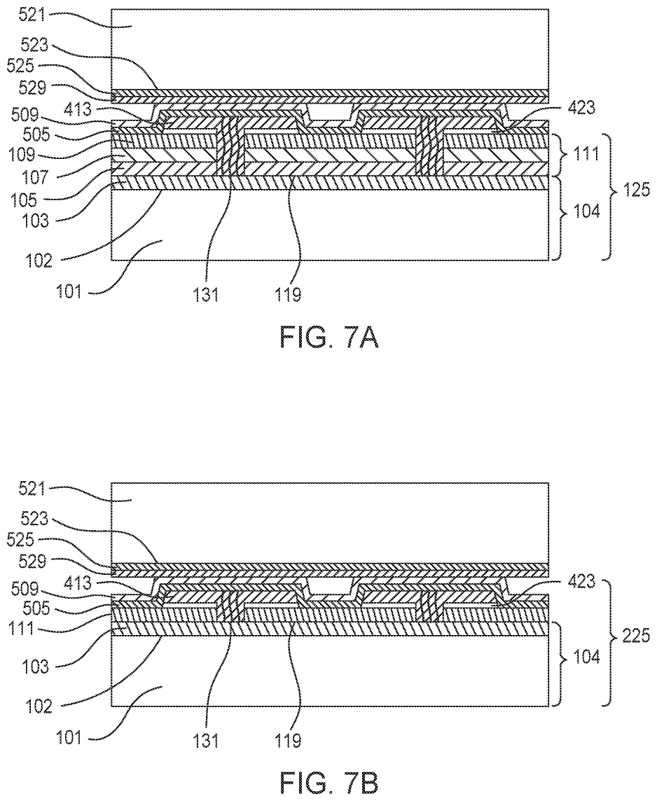

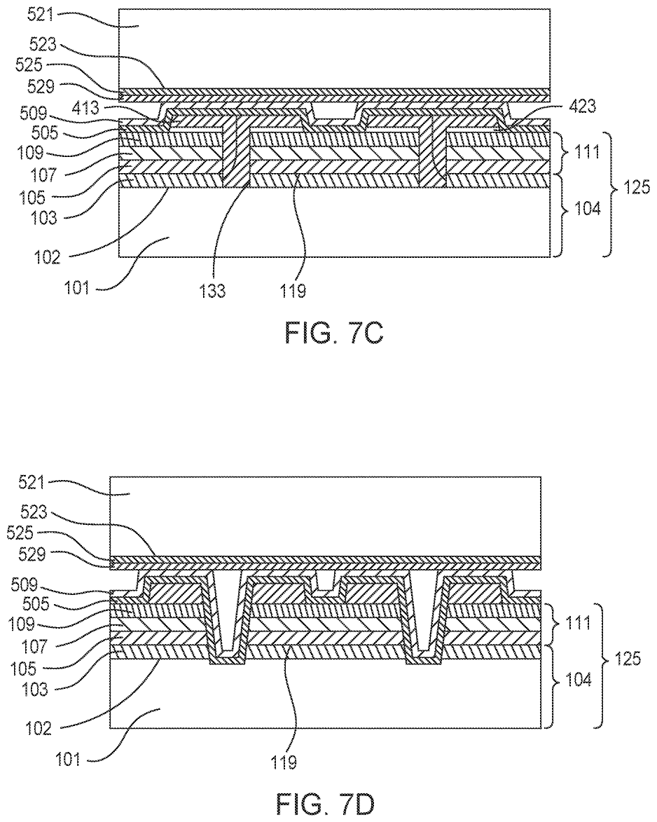

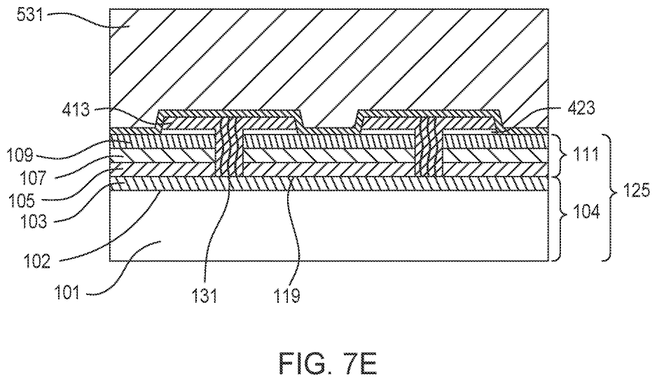

Referring to FIGS. 7A-7D, handle bonding layer 529 may then be placed in contact with epilayer bonding layer 509 and bonded, for the configurations shown schematically in FIGS. 7A-7D, respectively. In one specific embodiment, the bonding comprises wafer bonding. In another specific embodiment, the bonding comprises a eutectic die attach or die bonding operation. In a particular embodiment, the bonding operation is performed in a clean room, with less than 10,000, less than 1,000, less than 100, or less than 10 particles per cubic centimeter in the air. Particles may be removed from at least one of the surfaces immediately prior to bonding by spraying, brushing, or rinsing with ionized nitrogen, a CO₂ jet, CO₂ snow, high-resistivity water, an organic solvent, such as methanol, ethanol, isopropanol, acetone, or the like. In some embodiments, the corresponding bonding layers are brought into contact while immersed in a liquid. Optionally, at least one of the bonding layers is exposed to a plasma to enhance the strength of the formed bond.

Template substrate 101 may be pressed against handle substrate 521 with a pressure between about 0.001 megapascals and about 100 megapascals. In some embodiments, van der Waals forces or capillarity associated with nascent melting of the adhesion layer(s) are sufficient to obtain a good bond and very little or no additional applied force is necessary. Template substrate 101 and handle substrate 521 may be heated to a temperature between about 30 degrees Celsius and about 950 degrees Celsius, between about 30 degrees Celsius and about 400 degrees Celsius, between about 30 degrees Celsius and about 200 degrees Celsius to strengthen the bond. In some embodiments, heating of template substrate 101 and handle substrate 521 is performed while they are placed in mechanical contact and/or mechanically loaded against one another.

Referring to FIG. 7E, in another set of embodiments, a deposited-handle substrate 531 is formed on the non-coalesced group III metal nitride layer 413 grown over patterned, masked template 125 by a deposition process rather than by bonding to a pre-existing handle substrate. The deposited-handle substrate 531 may be formed or deposited directly on group III metal nitride layer 413, for example, by CVD, by HVPE or by a process similar to that described in U.S. Pat. No. 10,094,017. In certain embodiments, handle substrate 531 is characterized by an x-ray diffraction pole figure having a (0002) reflection at an angle within 10 degrees, within 5 degrees, within 2 degrees, or within 1 degree of a normal to its surface and where the full-width-at-half-maximum (FWHM) of the (0002) reflection in a χ- (or α-) scan is less than or equal to 20 degrees, less than or equal to 10 degrees, less than or equal to 5 degrees, or less than or equal to 3 degrees, as described above. In certain embodiments, a protective layer 535 is deposited on group III metal nitride layer 413 prior to depositing deposited-handle substrate 531. In certain embodiments, protective layer 535 consists of or includes at least one of Mg, Ca, Sr, Hf, Zr, B, Al, Si, P, Zn, Ga, Si, Ge, Sc, Y, R, where R is a rare earth element, Au, Ag, Ni, Ti, Cr, W, Mo, Ta, Zn, Cd, In, Sn, Sb, Tl, or Pb, or an oxide, nitride, oxynitride, or fluoride thereof. In certain embodiments, protective layer 535 is deposited by one or more of thermal evaporation, electron-beam evaporation, sputtering, chemical vapor deposition, plasma-enhanced chemical vapor deposition, high density plasma chemical vapor deposition, electron cyclotron resonance plasma chemical vapor deposition, atomic layer deposition or the like, or by thermal oxidation, nitridation, or fluorination of a deposited metallic film. In certain embodiments, protective layer 535 includes two or more layers, such as an adhesion layer in addition to an inert layer. The thickness of protective layer 535 may between about 1 nanometer and about 10 microns, or between about 10 nanometers and about 1 micron. Protective layer 535 may protect group III metal nitride layer 413 during the process steps associated with deposition of deposited-handle substrate 531 on group III metal nitride layer 413 and may also serve as an etch stop and growth barrier during subsequent process steps.

The specific embodiment illustrated schematically in FIG. 7E involves deposition of a polycrystalline group III metal nitride on the LEO substrate shown schematically in FIG. 5A. However, the deposition process can alternatively be performed on the substrate shown schematically in FIG. 5B, on the sidewall LEO substrate shown schematically in FIG. 5C, or on a substrate from which high-dislocation-density regions have been removed, as shown schematically in FIG. 5D, all of which are considered to be within the scope of the current disclosure.

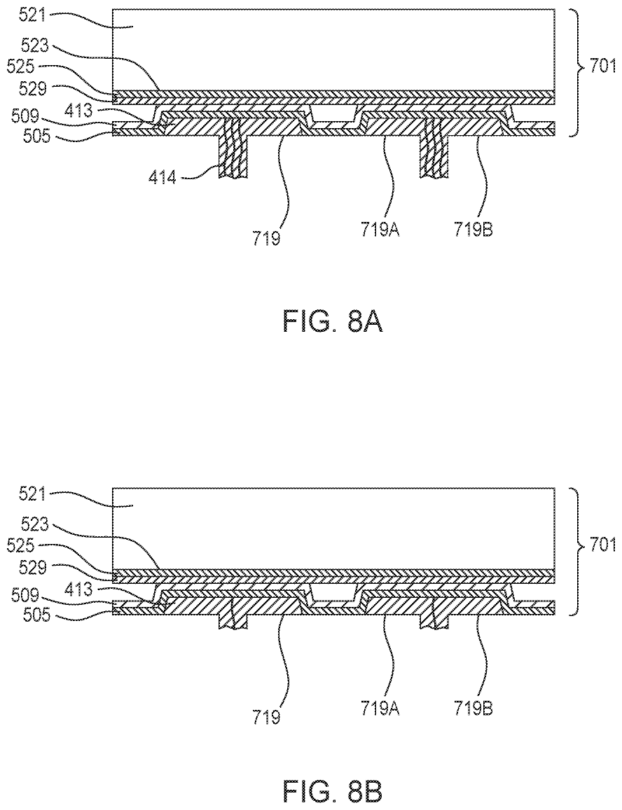

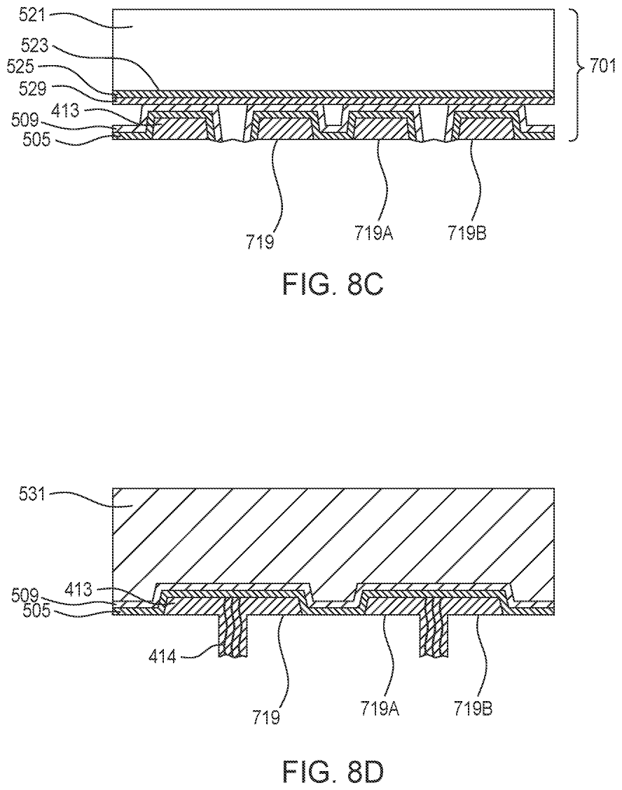

Referring to FIGS. 8A-8D, template substrate 101 is then removed from the configurations shown schematically in FIG. 7A or 7B or FIGS. 7C-7E, respectively, to form composite substrate 701, that includes an exposed surface 719 of the group III metal nitride layer 413. In general, surface 719 has the opposite-signed crystallographic orientation as original surface 119 of group III metal nitride layer 103. For example, if surface 119 had a Ga-face, (0001) orientation, then surface 719 has a N-face, (000-1) orientation, and vice-versa. If surface 119 had an m-plane orientation then surface 719 has a similar m-plane orientation, but any miscut now is in the opposite direction (e.g., toward (0001) rather than toward (000-1). If surface 119 had a semipolar orientation, e.g., (20-21), then surface 719 has an opposite-signed (20-2-1) orientation. In certain embodiments, template substrate 101 is removed by a selective chemical etching process. In a specific embodiment, template substrate 101 consists of or includes silicon and is removed by dissolution in a solution comprising at least one of HF and HNO₃. In another specific embodiment, template substrate 101 consists of or includes sapphire and is removed by dissolution in a melt comprising KBF₄, Na₃AlF₆, or another composition capable of selective dissolution of alumina, as described in U.S. Pat. No. 7,527,742, which is hereby incorporated by reference in its entirety. In certain embodiments, template substrate 101 is removed by grinding, lapping, polishing or other mechanical means. In certain embodiments, the template substrate is removed by laser ablation. In certain embodiments, a CTE mismatch between template substrate 101 and handle substrate 521 or 531 is sufficiently large to cause spontaneous delamination and/or cracking of template substrate 101, enabling easy mechanical removal. In certain embodiments, some or all of lateral portions of epilayer adhesion layer 505 and/or epilayer bonding layer 509, if present, are also removed during or subsequent to removal of template substrate 101.

Referring again to FIGS. 8A-8D, typically some wing tilt will be present in the wing regions of group III metal nitride layer 413, so that wing surface 719A of a first subset of wings (for example, “left” wings) will have a slightly different crystallographic orientation than wing surface 719B of a second subset of wings (for example, “right” wings). For example, a tilt angle between each of wing surfaces 719A and 719B and the negative of the orientation of original surface 119 of group III metal nitride layer 103 may have an average value between 0.01 degree and about 0.2 degree, or between about 0.02 degree and about 0.15 degree, or between about 0.03 degree and about 0.1 degree, with the average value of the difference of the crystallographic orientations of wing surfaces 719A and the crystallographic orientations or wing surfaces 719B being about twice these values. The tilt angles of each of wing surfaces 719A and 719B may be characterized by a distribution having a standard deviation between about 0.01 degree and about 0.1 degree.

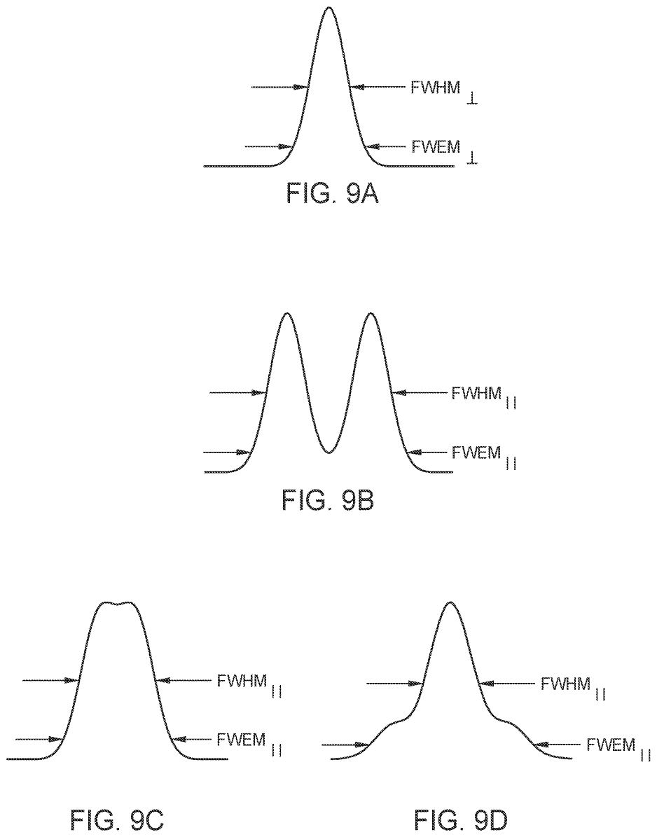

Referring to FIGS. 9A-9D, the tilt angle distributions of wing surfaces 719A and 719B may be quantified by x-ray diffraction, using methods that are well known in the art. Referring to FIG. 9A, an x-ray rocking curve (XRC) in a direction perpendicular to the page of FIGS. 8A-8D may be characterized by a single ω peak associated with a particular reflection, for example, (002), (004), or (006), and have a full-width-at-half maximum FWHM_{⊥} having a value between about 30 arc second and about 600 arc seconds, between about 75 arc seconds and about 450 arc seconds, or between about 100 arc seconds and about 250 arc seconds. Note that in this particular XRC orientation, the x-rays may be in a plane that is parallel to the pattern, which is perpendicular to the page, and the rocking axis is perpendicular to the pattern. The rocking curve may be further characterized by a full-width-at-eighth maximum FWEM_{⊥} having a value between about 60 arc second and about 1500 arc seconds, between about 150 arc seconds and about 900 arc seconds, or between about 200 arc seconds and about 500 arc seconds. Referring to FIG. 9B, in a case where the difference in wing tilt angle between wing surfaces 719A and wing surfaces 719B exceeds the value of FWHM_{⊥}, an x-ray rocking curve in a direction parallel to the page of FIGS. 8A-8D may be characterized by a double ω peak associated with a particular reflection, for example, (002), (004), or (006), each of which may be characterized by an individual full-width-at-half maximum within about 30%, within about 20%, or within about 10% of FWHM_{⊥}. Note that in this particular XRC orientation, the x-rays may be in a plane that is perpendicular to the pattern and parallel to the page, and the rocking axis is parallel to the pattern. Referring to FIG. 9C, in a case where the difference in wing tilt angle between wing surfaces 719A and wing surfaces 719B is less than the value of FWHM_{⊥}, an x-ray rocking curve in a direction parallel to the page of FIGS. 8A-8D may be characterized by a quasi-single ω peak associated with a particular first-order reflection, for example, (002), (004), or (006), having a full-width-at-half maximum FWHM_{∥} value that is greater than the FWHM_{⊥} value. Depending on the relative values of the difference in tilt angles and the FHWM of the individual sets of wings, a local minimum may or may not be observable near the intensity maximum. In certain embodiments, for example, where an x-ray rocking curve has two or more distinct peaks, such as that shown schematically in FIG. 9B, a difference in tilt angles may be extracted directly from the difference in ω values of the outermost peaks. In other embodiments, where the peaks may not be entirely distinct, such as that shown schematically in FIGS. 9C and 9D, a peak-fitting procedure may be employed, and the difference in tilt angles may be extracted from the difference in peak positions of the fitted peaks. In still other embodiments, where peak-fitting may not be possible, an estimate of the difference in tilt angles may be obtained by simply subtracting the FWHM_{⊥} value from the FWHM_{∥} value. Referring to FIG. 9D, depending on the distribution in tilt angles of the wing surfaces 719, the x-ray rocking curve may have one or more shoulders on the main peak rather than a simple doublet. For example, wing regions grown from a pattern of openings 120 similar to that shown schematically in FIG. 4G may be characterized by more than two types of wing surfaces 719. In such a case, the difference in the rocking curves in the “parallel” and “perpendicular” orientations may be more easily quantified by referring to the full-width-at-eighth-maximum (FWEM) value rather than the full-width-at-half-maximum (FWHM) value. Referring again to FIG. 9B, in cases where a double peak is present we define FWHM_{∥} and FWEM_{∥} as the difference in diffraction angles (ω) between the “outer” half-maximum, or eight-maximum, respectively, values of the two peaks together, rather than treating each peak individually. In a specific embodiment, group III metal nitride layer 103 has a crystallographic orientation within about 1 degree of (0001), pattern openings 113 or isolated growth centers 230 have an orientation substantially in a <10-10>m direction, growth of the lateral wings occurs substantially in a <11-20> a direction, and surfaces 719 are characterized by FWHM_{⊥} and FWEM_{⊥} values measured from a (002), (004), or (006) reflection rocking about an a axis and by FWHM_{∥} and FWEM_{∥} values measured from the same reflection, rocking about an orthogonal m-axis.

In certain embodiments, such as those shown schematically in FIGS. 4D-4F, the pattern openings or isolated growth centers are predominantly oriented in one crystallographic direction, and the x-ray rocking curve measurements described above can be performed with the diffractometer slits wide open, so that a relatively large area of the substrate is illuminated by the x-ray beam. In other embodiments, however, the pattern openings may rotate from one orientation to another in various domains across the substrate. In such a case, it may be necessary to narrow the slits of the x-ray diffractometer so that, for example, only a 1- or 2-millimeter-wide area is illuminated during rocking-curve measurements in order to preferentially illuminate patterns with one wing tilt orientation. In one example, the x-ray rocking curves are measured with the illuminated area being limited to being 2 millimeters wide by slits in the diffractometer. In certain embodiments, such as that shown in FIG. 4G, there will be mix of wing orientations regardless of the size of the x-ray spot. Even in this case, however, the x-ray rocking curve in one direction (for example, vertical in FIG. 4G), will sample the “perpendicular” orientation more than the parallel orientation, whereas the reverse is true when the rocking curve is measured in an orthogonal orientation (for example, horizontal in FIG. 4G).

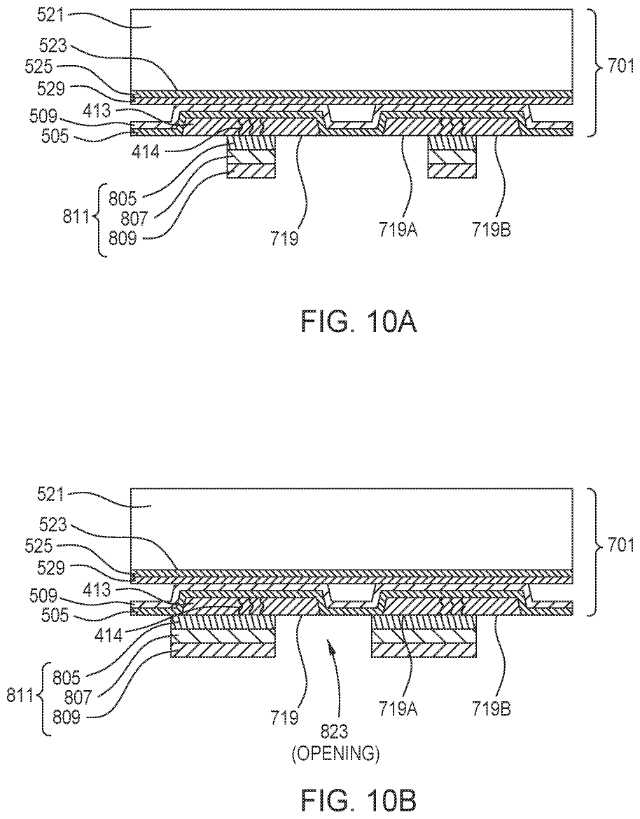

In certain embodiments, composite substrate 701 undergoes additional processing to form a composite seed crystal useful for bulk crystal growth, for example, ammonothermal crystal growth. In certain embodiments, group III metal nitride layer 413 is planarized and/or thinned, for example, by wet etching, by dry etching, by lapping, by grinding, by polishing, or by chemical mechanical polishing. In certain embodiments, one, two, or more holes is drilled in composite substrate 701 to facilitate hanging for ammonothermal crystal growth. In certain embodiments, one or more exposed surfaces of handle substrate 521 or 531 are masked, for example, with one or more of a handle adhesion layer, a handle diffusion barrier layer, or a handle inert layer, for example, having similar compositions to those described above for adhesion layer 105, diffusion-barrier layer 107, and inert layer 109, respectively. In certain embodiments, one or more regions of exposed surface 719 is masked, for example, to cover regions with elevated concentrations of threading dislocations 414, as shown schematically in FIG. 10A. In certain embodiments, the epilayer mask 811 includes or more of epilayer adhesion layer 805, epilayer diffusion-barrier layer 807, and epilayer inert layer 809, respectively, for example, having similar compositions to those described above for adhesion layer 105, diffusion-barrier layer 107, and inert layer 109, respectively. In certain embodiments, only one of wing surfaces 719A and 719B is left exposed, as shown schematically in FIG. 10B. In certain embodiments, only a fraction, for example, between 1% and about 90%, between 2% and about 50%, or between about 3% and about 25% of at least one of wing surfaces 719A and 719B are left exposed through openings 823. In certain embodiments, rather than at least one of wing surfaces 719A and 719B for each individual segment of group III metal nitride layer 413 being left exposed, only a fraction of them may be left exposed. Put differently, the pitch between adjacent openings 823 may be a multiple of L, for example, 2L, 3L, 4L, 8L, or the like, where L is the pitch of the original pattern (cf. FIG. 2C)

Composite substrate 701 may then be suspended on a seed rack and placed in a sealable container, such as a capsule, an autoclave, or a liner within an autoclave. In certain embodiments, one or more pairs of substrates are suspended back to back, with the exposed large-area surfaces 719 facing outward. A group III metal source, such as polycrystalline group III metal nitride, at least one mineralizer composition, and ammonia (or other nitrogen containing solvent) are then added to the sealable container and the sealable container is sealed. The mineralizer composition may consist of or include an alkali metal such as Li, Na, K, Rb, or Cs, an alkaline earth metal, such as Mg, Ca, Sr, or Ba, or an alkali or alkaline earth hydride, amide, imide, amido-imide, nitride, or azide. The mineralizer may consist of or include an ammonium halide, such as NH₄F, NH₄Cl, NH₄Br, or NH₄I, a gallium halide, such as GaF₃, GaCl₃, GaBr₃, Gal₃, or any compound that may be formed by reaction of one or more of F, Cl, Br, I, HF, HCI, HBr, HI, Ga, GaN, and NH₃. The mineralizer may consist of or include other alkali, alkaline earth, or ammonium salts, other halides, urea, sulfur or a sulfide salt, or phosphorus or a phosphorus-containing salt. The sealable container may then be placed in a high-pressure apparatus, such as an internally heated high pressure apparatus or an autoclave, and the high pressure apparatus sealed.

The sealable container, containing composite substrate 701, is then heated to a temperature above about 400 degrees Celsius and pressurized above about 50 megapascal to perform ammonothermal crystal growth.

In certain embodiments, a non-ammonothermal bulk crystal growth process is performed on composite substrate 701, such as HVPE or flux growth.

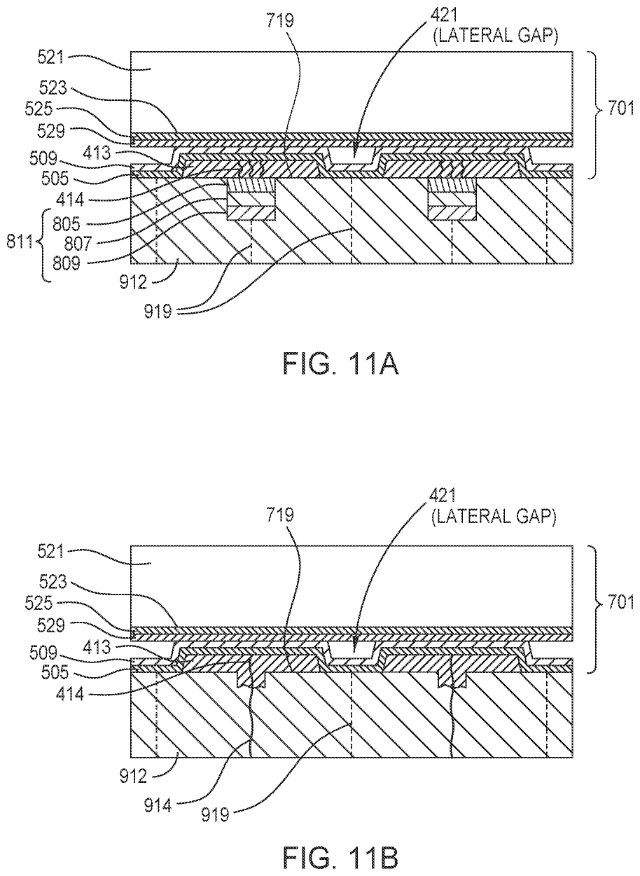

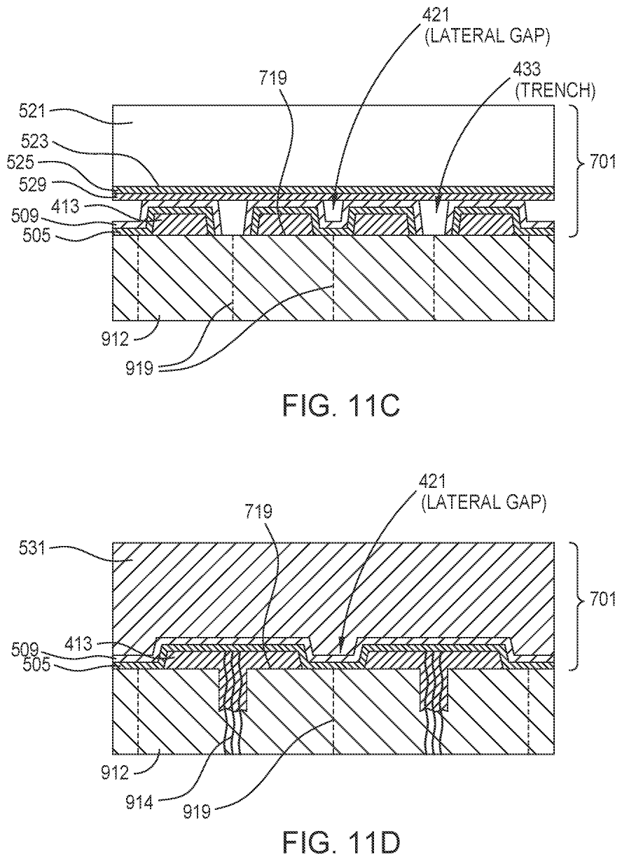

Referring to FIG. 11A, in one embodiment, during a bulk crystal growth process on a composite seed crystal shown schematically in FIG. 10A, for example, an ammonothermal crystal growth process, bulk group III metal nitride material grows vertically on surface 719 of group III metal nitride layer 413, forming bulk-grown group III metal nitride layer 912. Bulk-grown group III metal nitride layer 413 may also grow laterally over masks 811 and with respect to lateral gaps 421, if they are present, and may form coalescence fronts 919 where adjacent laterally-growing centers meet. Bulk-grown group III metal nitride layer 912 may have a thickness between about 10 micrometers and about 100 millimeters, between about 100 micrometers and about 20 millimeters, or between about 200 micrometers and about 5 millimeters.

Referring to FIGS. 11B, 11C, and 11D, in additional embodiments, during a bulk crystal growth process on a composite substrate 701 shown schematically in FIGS. 8B, 8C, and 8D, respectively, for example, an ammonothermal crystal growth process, bulk group III metal nitride material grows vertically on surface 719 of group III metal nitride layer 413, forming bulk-grown group III metal nitride layer 912. Bulk-grown group III metal nitride layer 912 may also grow laterally with respect to lateral gaps 421 and/or trenches 433, if they are present, and may form coalescence fronts 919 where adjacent laterally-growing centers meet. Threading dislocations 914 (FIG. 11B) may form as extensions of threading dislocations 414 that are present in group III metal nitride layer 413 if they are left unmasked. Referring to FIG. 11C, the removal of high-dislocation regions in group III metal nitride layer 413 by formation of trench 433 (see also FIG. 5D) may enable a reduction in the dislocation density of bulk-grown group III metal nitride layer 912 at the possible cost of an additional coalescence front 919.

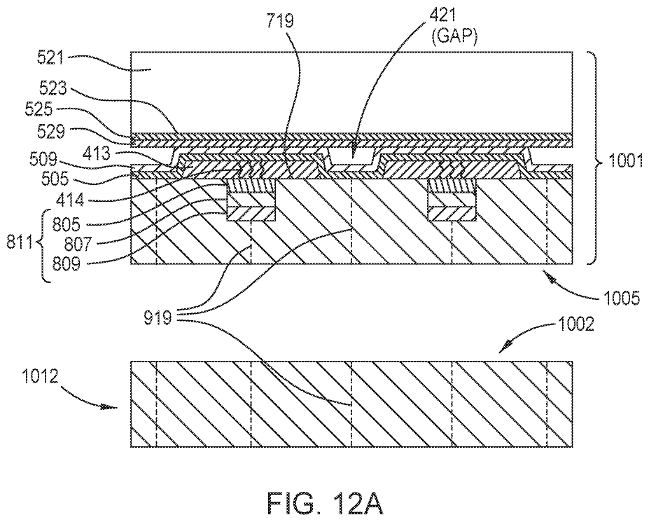

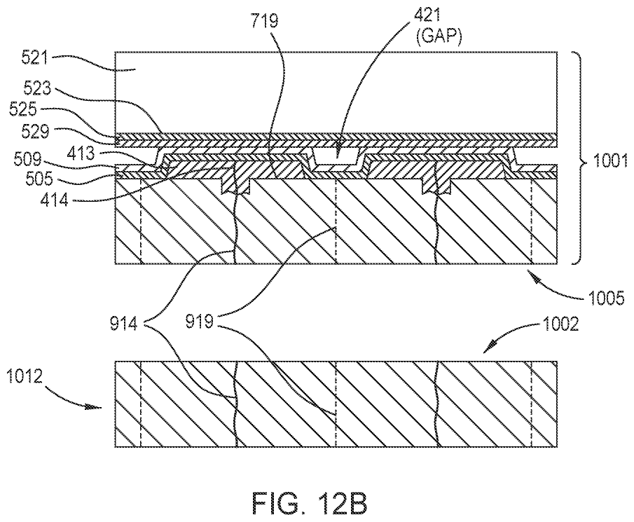

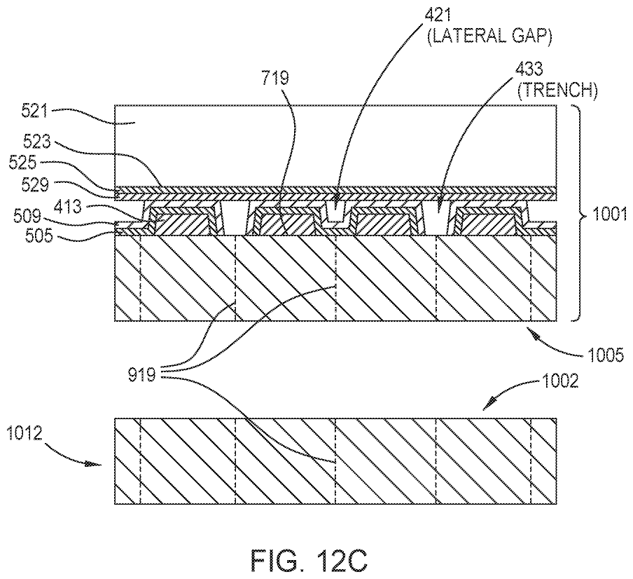

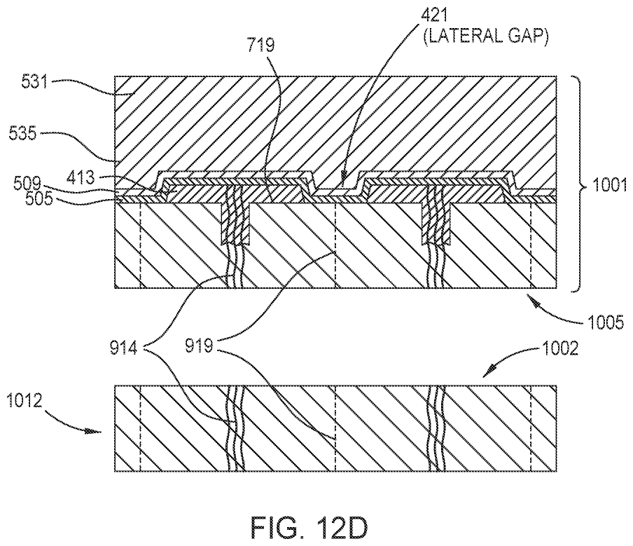

In certain embodiments, bulk-grown group III metal nitride layer 912, for example, as shown schematically in FIGS. 11A-11D, is separated from handle substrate 521 or 531, forming free-standing bulk group III metal nitride crystal 1012 with newly-formed surface 1002, as shown schematically in FIGS. 12A-12D, respectively. In a preferred embodiment, free-standing bulk group III metal nitride crystal 1012 is formed by a single-wire-sawing process, recovering composite substrate 1001 with freshly-formed surface 1005. In certain embodiments, residual damage on freshly-formed surface 1005 is removed by one or more of grinding, polishing, wet chemical etching, dry etching, and chemical mechanical polishing, and composite substrate 1001 can be re-used as a seed crystal for bulk crystal growth. In other embodiments, handle substrate 521 or 531 may be removed by one or more of grinding, wet chemical etching, or the like. In certain embodiments, the crystallographic orientation of newly-formed surface 1002 is measured by x-ray diffraction. In certain embodiments, the crystallographic orientation of newly-formed surface 1002 is adjusted, to a predetermined value, by performing surface grinding.

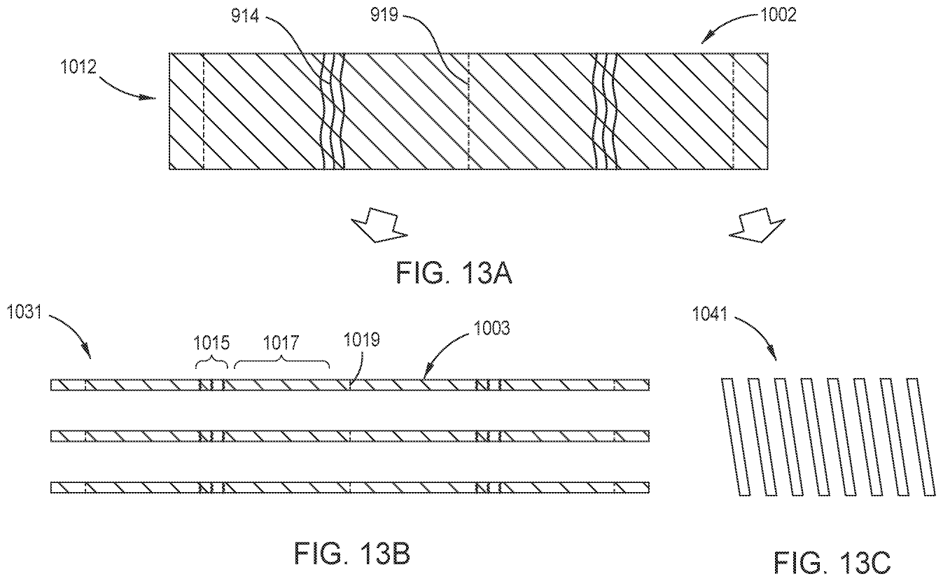

Referring again to FIGS. 12A-12D and also to FIG. 13A, in certain embodiments, the edge of free-standing bulk group III metal nitride crystal 1012 is ground to form a cylindrically-shaped free-standing bulk group III metal nitride boule. In certain embodiments, one or more flats is ground into the side of the cylindrically-shaped free-standing bulk group III metal nitride boule. In certain embodiments, the cylindrically-shaped free-standing bulk group III metal nitride boule is sliced into one or more free-standing group III metal nitride wafers 1031 having a crystallographic orientation on at least one large-area surface that is within about 5 degrees, within about 2 degrees, within about 1 degree, within about 0.3 degree, or within about 0.1 degree, of that of surface 1002 (possibly after adjustment by surface grinding), as shown in FIG. 13B. In a specific embodiment, free-standing group III metal nitride wafers 1031 have a crystallographic orientation within about 5 degrees, within about 2 degrees, within about 1 degree, of (000±1) or {10-10}. In certain embodiments, the edge of free-standing bulk group III metal nitride boule 1012 is not ground to a cylindrical shape and free-standing group III metal nitride wafers 1031 have a hexagonal, rectangular, or other non-circular shape. Such non-circular wafers may be ideal for use as seed crystals, for example. Such seed crystals may be grown upon using processes similar to those described above in connection with FIGS. 11A-11D, producing crystals having similar patterns of coalescence fronts and threading dislocations.

In certain embodiments, free-standing bulk group III metal nitride crystal 1012 is instead sliced at an oblique angle to form one, two, or more free-standing group III metal nitride non-polar/semipolar (NP/SP) wafers 1041, as shown schematically in FIG. 13C. In a specific embodiment, at least one surface of free-standing group III metal nitride NP/SP wafers 1041 has a crystallographic orientation within 5 degrees, within about 2 degrees, within about 1 degree, within about 0.3 degree, or within about 0.1 degree of {10-10}, {60-6±1}, {50-5±1}, {40-4±1}, {30-3±1}, {50-5±2}, {70-7±3}, {20-2±1}, {30-3±2}, {40-4±3}, {50-5±4}, {10-1±1}, {10-1±2}, or {10-1±3}. The slicing may be performed by multi-wire sawing, multi-wire slurry sawing, slicing, inner-diameter sawing, outer-diameter sawing, cleaving, ion implantation followed by exfoliation, spalling, laser cutting, or the like. One or more large-area surface of free-standing group III metal nitride wafers 1031 or 1041 may be lapped, polished, etched, electrochemically polished, photoelectrochemically polished, reactive-ion-etched, and/or chemical-mechanically polished according to methods that are known in the art. In certain embodiments, a chamfer, bevel, or rounded edge is ground into the edges of free-standing group III metal nitride wafers 1031 or 1041. The free-standing group III metal nitride wafers 1031 or 1041 may have a diameter of at least about 100 millimeters, at least about 150 millimeters, at least about 200 millimeters, at least about 300 millimeters, at least about 400 millimeters, or at least about 600 millimeters and may have a thickness between about 50 micrometers and about 10 millimeters, between about 150 micrometers and about 3 millimeters, or between about 250 micrometers and about 1 millimeter. One or more large-area surface of free-standing group III metal nitride wafers 1031 or 1041 may be used as a substrate for group III metal nitride growth by chemical vapor deposition, metalorganic chemical vapor deposition, hydride vapor phase epitaxy, molecular beam epitaxy, flux growth, solution growth, ammonothermal growth, among others, or the like.

Referring again to FIG. 13B, free-standing group III metal nitride wafer 1031 may include coalescence-front regions 1019, also referred to herein as first regions, where threading dislocations associated with coalescence fronts 919 intersect surface 1003 of free-standing group III metal nitride wafer 1031. Coalescence-front regions 1019 may include or consist of a pattern of locally-approximately-linear arrays of threading dislocations, for example, edge dislocations, with a linear concentration between about 5 cm⁻¹ and about 10⁵ cm⁻¹, between about 10 cm⁻¹ and about 10⁴ cm⁻¹, or between about 20 cm⁻¹ and about 10³ cm⁻¹. In certain embodiments, coalescence-front regions 1019 include a “sharp boundary” that has a width less than about 25 micrometers or less than about 10 micrometers that is disposed between adjacent low-dislocation-density regions 1017, also referred to herein as second regions or as wing regions. In other embodiments, coalescence-front regions 1019 include an “extended boundary” that has a width between about 25 micrometers and about 1000 micrometers or between about 30 micrometers and about 250 micrometers that is disposed between adjacent low-dislocation-density regions 1017, depending on the growth conditions.

Referring to FIG. 13C, coalescence-front regions, that is, regions that are characterized by a locally-approximately-linear arrays of threading dislocations, for example, edge dislocations, may also be present in free-standing group III metal nitride NP/SP wafers 1041, and may be formed by cross-slicing coalescence fronts 919. In this case, the concentration of threading dislocations within the coalescence-front regions may be somewhat lower because of the cross-slicing, for example, between about 2 cm⁻¹ and about 3×10⁴ cm⁻¹, between about 5 cm⁻¹ and about 3×10³ cm⁻¹, or between about 10 cm⁻¹ and about 300 cm⁻¹.

Referring again to FIG. 13B and also to FIGS. 5A-5E and 11A-11D, low-dislocation-density regions 1017 on free-standing group III metal nitride wafer 1031 may be formed by one or more of vertical growth from wing regions 417 of group III metal nitride layer 413, lateral growth over masks 811, or lateral growth over gaps 421 or trenches 433. Low-dislocation-density regions 1017 may be characterized by a threading-dislocation density between about 1 cm⁻² and about 10⁶ cm⁻², between about 10 cm⁻² and about 10⁵ cm⁻², or between about 100 cm⁻² and about 10⁴ cm⁻². Low-dislocation-density regions 1017 may also be characterized by concentration of stacking faults below about 10³ cm⁻¹, below about 10² cm⁻¹, below about 10 cm⁻¹, below about 1 cm⁻¹, or below about 0.1 cm⁻¹.

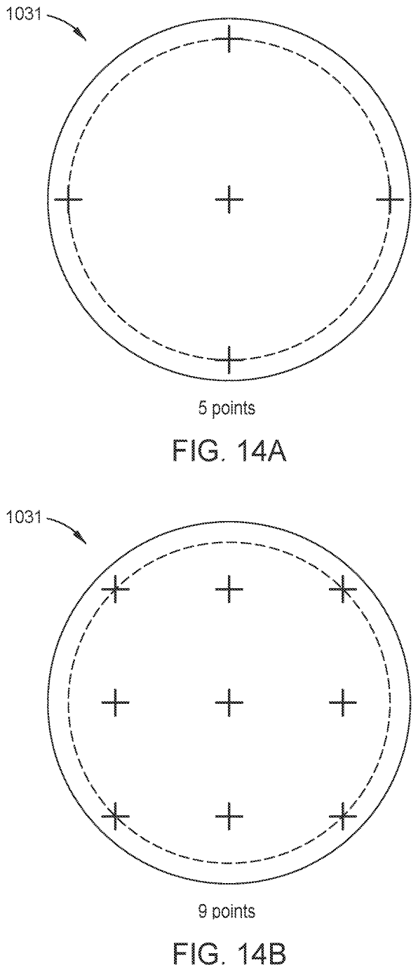

Referring again to FIGS. 13B, 13A, 9A, 9B, 9C, and 8A-D, wing tilt present in composite substrate 701 will in general persist during the subsequent crystal growth and wafering processes. As a result, as illustrated schematically in FIGS. 14A and 14B (with one or more optional wafer flats not shown), at each of five points or at each of nine points distributed evenly within the central 80% of its area, a free-standing group III metal nitride wafer 1031 may be characterized by a x-ray rocking curve about a first direction (for example, parallel to the original pattern) that has a full-width-at-half-maximum FWHM_{∥} value that is greater than the FWHM_{⊥} value measured about a second direction orthogonal to the first direction (for example, perpendicular to the original pattern). At each of five points or at each of nine points distributed evenly within the central 80% of its area, a free-standing group III metal nitride wafer 1031 may be characterized by a x-ray rocking curve about a first direction (for example, parallel to the original pattern) that has a full-width-at-eighth-maximum FWEM₈₁ value that is greater than the FWEM_{⊥} value measured about a second direction orthogonal to the first direction (for example, perpendicular to the original pattern). In some embodiments, an x-ray rocking curve at each of the five or nine points in the first direction is characterized by two peaks, with a peak separation corresponding to a difference in crystallographic orientation between about 0.01 degrees and about 0.4 degrees, between about 0.02 degrees and about 0.2 degrees, or between about 0.03 degrees and about 0.15 degrees. In certain embodiments, an x-ray rocking curve at each of the five points or at each of the nine points in the first direction is characterized by a single peak having a full-width-at-half-maximum value FWHM_{∥} value that is greater than the FWHM_{⊥} value of a single peak measured in the second direction, by a difference corresponding to a difference in crystallographic orientation between about 0.01 degrees and about 0.2 degrees, between about 0.02 degrees and about 0.1 degrees, or between about 0.03 degrees and about 0.075 degrees. In certain embodiments, an x-ray rocking curve at each of the five points or at each of the nine points in the first direction is characterized by a single peak having a full-width-at-eighth-maximum FWEM_{∥} value that is greater than the FWEM_{⊥} value of a single peak measured in the second direction, by a difference corresponding to a difference in crystallographic orientation between about 0.01 degrees and about 0.2 degrees, between about 0.02 degrees and about 0.1 degrees, or between about 0.03 degrees and about 0.075 degrees. In some embodiments, at each of five points distributed evenly within a central 80% of an area of a first surface of a free-standing crystal, the free-standing crystal is further characterized by a x-ray rocking curve in a first direction having a full-width-at-half-maximum FWHM_{∥} value that is greater than the FWHM_{⊥} value of an x-ray rocking curve measured in a second direction by a difference corresponding to a difference in crystallographic orientation between about 0.01 degrees and about 0.4 degrees.

It has been found that bulk crystals grown on laterally-grown seed crystals in which the lateral gap 421 (cf. FIGS. 5A-5C) is zero (i.e., fully coalesced) are essentially always characterized by x-ray diffraction rocking curves that are single-peaked. The presence of strain and/or poor crystallinity can case the FWHM values to be relatively broad, but double-peaked structures like those shown schematically in FIG. 9B in ammonothermally crystals grown on LEO-type seed crystals that have been fully coalesced have not been observed over the central 80% of the area of the crystals during the development of the conventional processes described herein or in the literature. Crystals that exhibit double- or multi-peaked XRD profiles are generally regarded as undesirable due to an indication that multiple crystallites are present in the sample, so crystals of the type disclosed herein have generally not been pursued. It has been found that, as long as the crystallographic misorientation associated with the domains represented by the double- or multiple-peaks is small, for example, less than 0.2 degree, less than 0.1 degree, less than 0.05 degree, or less than 0.02 degree, then the magnitude of stress within the crystal is too small to cause significant cracking. In addition, since the impact of a typical range in miscut variation across a large-area wafer surface 1003 (FIG. 13B) will be small for crystals grown by the methods described herein versus conventional crystal growth techniques that utilize dissimilar material containing crystal growth supporting substrates (e.g., non-GaN substrates) at some point in their growth history that induce residual stress, strain and possibly crystal defects in the conventionally grown crystals. Therefore, a large-area substrate formed by the techniques described herein can be advantageously and cost-effectively used in the fabrication of a laser diode, a power device, or other device application.

Referring again to FIG. 13B and also to FIGS. 5A-5E and 11A-11D, in certain embodiments, free-standing group III metal nitride wafer 1031 may also include one or more high-dislocation-density regions 1015, also referred to herein as third regions, which may be formed by vertical growth from window regions 415 of group III metal nitride layer 413. High-dislocation-density regions 1015, if present, may be characterized by a threading dislocation density between about 10³ cm⁻² and about 10⁸ cm⁻², between about 10⁴ cm⁻² and about 10⁷ cm⁻², or between about 10⁵ cm⁻² and about 10⁵ cm⁻². High-dislocation-density regions 1015, if present, may also be characterized by concentration of stacking faults below about 10³ cm⁻¹, below about 10² cm⁻¹, below about 10 cm⁻¹, or below about 1 cm⁻¹.

The concentration of threading dislocations, averaged over a large-area surface of the free-standing group III metal nitride boule 1031 or 1041, may be greater than 1 cm⁻², below about 10⁶ cm⁻², below about 10⁵ cm⁻², below about 10⁴ cm⁻², below about 10³ cm⁻², below about 10² cm⁻², or below about 10 cm⁻². The concentration of stacking faults, averaged over a large-area surface of the free-standing laterally-grown group III nitride boule or wafer, may be below about 10³ cm⁻¹, below about 10² cm⁻¹, below about 10 cm⁻¹, below about 1 cm⁻¹, or below about 0.1 cm⁻¹, or may be undetectable. In some embodiments, for example, after repeated re-growth on a seed crystal with a patterned array of dislocations, such as those associated with coalescence fronts or the third regions referenced above, and/or growth to a thickness greater than 2 millimeters, greater than 3 millimeters, greater than 5 millimeters, or greater than 10 millimeters, the positions of the threading dislocations may be displaced laterally to some extent with respect to the pattern of dislocations present in the seed crystal. In such a case the regions with a higher concentration of threading dislocations may be somewhat diffuse. However, the concentration of threading dislocations as a function of lateral position along a line on the surface will vary periodically, with a period between about 5 micrometers and about 20 millimeters, between about 200 micrometers and about 5 millimeters, or between about 500 micrometers and about 2 millimeters. The average concentration of threading dislocations within the periodically-varying region may vary by at least a factor of two, at least a factor of 5, at least a factor of 10, at least a factor of 30, at least a factor of 100, at least a factor of 300, or at least a factor of 1000.

The free-standing group III metal nitride boule wafer 1031 or 1041 may have a large-area crystallographic orientation within 5 degrees, within 2 degrees, within 1 degree, within 0.5 degree, within 0.2 degree, within 0.1 degree, within 0.05 degree, within 0.02 degree, or within 0.01 degree of (0001) +c-plane, (000-1) −c-plane, {10-10} m-plane, {1 1 −2 0} a-plane, {11-2±2}, {60-6±1}, {50-5±1}, {40-4±1}, {30-3±1}, {50-5±2}, {70-7±3}, {20-2±1}, {30-3±2}, {40-4±3}, {50-5±4}, {10-1±1}, {10-1±2}, {1 0 −1±3}, {2 1 −3±1}, or {3 0 −3±4}. The free-standing laterally-grown group III metal nitride boule or wafer may have an (h k i l) semipolar large-area surface orientation, where i=−(h+k) and/and at least one of h and k are nonzero.

A large-area surface of the free-standing group III metal nitride wafer 1031 or 1041 may be characterized by an average value of M/D that is less than 0.003 degree/mm, less than 0.002 degree/mm, less than 0.001 degree/mm, less than 0.0005 degree/mm, less than 0.0002 degree/mm, or less than 0.0001 degree/mm, where M is the miscut variation, in degrees, across the large-area surface and D is the maximum dimension or diameter of the large-area surface, in millimeters. The miscut variation M is defined as the difference in miscut, with respect to a nominal crystallographic orientation, between the maximum value of the miscut and the minimum value of the miscut across the large-area surface.

The free-standing group III metal nitride boule 1012 or wafer 1031 or 1041 may have a symmetric x-ray rocking curve full width at half maximum (FWHM) less than about 300 arcsec, less than about 200 arcsec, less than about 150 arcsec, less than about 100 arcsec, or less than about 50 arcsec. The free-standing group III metal nitride boule 1012 or wafer 1031 or 1041 may have a crystallographic radius of curvature greater than 1 meter, greater than 10 meters, greater than 100 meters, or greater than 1000 meters, in at least one or at least two independent or orthogonal directions.

The free-standing group III metal nitride boule 1012 or wafer 1031 or 1041 may be characterized by a wurtzite structure substantially free from any cubic entities or other crystal structures, the other structures being less than about 0.1% in volume in reference to the substantially wurtzite structure.

A free-standing group III metal nitride wafer 1031 or 1041 may be characterized by a total thickness variation (TTV) of less than about 25 micrometers, less than about 10 micrometers, less than about 5 micrometers, less than about 2 micrometers, or less than about 1 micrometer, and by a macroscopic bow that is less than about 200 micrometers, less than about 100 micrometers, less than about 50 micrometers, less than about 25 micrometers, or less than about 10 micrometers. A large-area surface of the free-standing group III metal nitride wafer 1031 or 1041 may have a concentration of macro defects, with a diameter or characteristic dimension greater than about 100 micrometers, of less than about 2 cm⁻², less than about 1 cm⁻², less than about 0.5 cm⁻², less than about 0.25 cm⁻², or less than about 0.1 cm⁻²The variation in miscut angle across a large-area surface of the free-standing group III metal nitride wafer may be less than about 1 degree, less than about 0.5 degree, less than about 0.2 degree, less than about 0.1 degree, less than about 0.05 degree, or less than about 0.025 degree in each of two orthogonal crystallographic directions. The root-mean-square surface roughness of a large-area surface of the free-standing group III metal nitride wafer 1031 or 1041, as measured over an area of at least 10 μm×10 μm, may be less than about 0.5 nanometer, less than about 0.2 nanometer, less than about 0.15 nanometer, less than about 0.1 nanometer, or less than about 0.10 nanometer. The free-standing group III metal nitride wafer 1031 or 1041 may be characterized by n-type electrical conductivity, with a carrier concentration between about 1×10¹⁷ cm⁻³ and about 3×10¹⁹ cm⁻³ and a carrier mobility greater than about 100cm² /V-s. In alternative embodiments, the free-standing group III metal nitride wafer 1031 or 1041 is characterized by p-type electrical conductivity, with a carrier concentration between about 1×10¹⁵ cm⁻³ and about 1×10¹⁹ cm⁻³. In still other embodiments, the free-standing group III metal nitride wafer 1031 or 1041 is characterized by semi-insulating electrical behavior, with a room-temperature resistivity greater than about 10⁷ ohm-centimeter, greater than about 10⁸ ohm-centimeter, greater than about 10⁹ ohm-centimeter, greater than about 10¹⁰ ohm-centimeter, or greater than about 10¹¹ ohm-centimeter. In certain embodiments, the free-standing group III metal nitride wafer 1031 or 1041 is highly transparent, with an optical absorption coefficient at a wavelength of 400 nanometers that is less than about 10 cm⁻¹, less than about 5 cm⁻¹, less than about 2 cm⁻¹, less than about 1 cm⁻¹, less than about 0.5 cm⁻¹ less than about 0.2 cm⁻¹, or less than about 0.1 cm⁻¹.

A wafer 1031 or 1041 formed by the one or more processes described above may be incorporated into a semiconductor structure. The semiconductor structure may comprise at least one AlₓIn_{y}Ga_{(1-x-y)}N epitaxial layer, where 0≤x, y, x+y≤1. The epitaxial layer may be deposited on the wafer, for example, by metalorganic chemical vapor deposition (MOCVD) or by molecular beam epitaxy (MBE), according to methods that are known in the art. At least a portion of the semiconductor structure may form a portion of a gallium-nitride-based electronic device or optoelectronic device, such as a light emitting diode, a laser diode, a photodetector, an avalanche photodiode, a photovoltaic, a solar cell, a cell for photoelectrochemical splitting of water, a transistor, a rectifier, and a thyristor; one of a transistor, a rectifier, a Schottky rectifier, a thyristor, a p-i-n diode, a metal-semiconductor-metal diode, high-electron mobility transistor, a metal semiconductor field effect transistor, a metal oxide field effect transistor, a power metal oxide semiconductor field effect transistor, a power metal insulator semiconductor field effect transistor, a bipolar junction transistor, a metal insulator field effect transistor, a heterojunction bipolar transistor, a power insulated gate bipolar transistor, a power vertical junction field effect transistor, a cascode switch, an inner sub-band emitter, a quantum well infrared photodetector, a quantum dot infrared photodetector, and combinations thereof. The gallium-nitride-based electronic device or optoelectronic device may be incorporated into a lamp or a fixture, such as a luminaire. The gallium-nitride-based electronic device or optoelectronic device, after singulation, may have lateral dimensions of at least 0.1 millimeter by 0.1 millimeter. The gallium-nitride-based electronic or optoelectronic device may have a maximum dimension of at least 8 millimeters and, for example, may comprise a laser diode. The gallium-nitride-based electronic or optoelectronic device may be entirely free of dislocations throughout its volume. For example, at a dislocation density of 10⁴ cm⁻², a substantial fraction of 0.1×0.1 mm² devices could be expected to be free of dislocations. At a dislocation density of 10² cm⁻², a substantial fraction of 1×1 mm² devices could be expected to be free of dislocations. The gallium-nitride-based electronic or optoelectronic device may be entirely free of stacking faults throughout its volume. For example, at a stacking fault density of 1 cm⁻¹, a substantial fraction of 10×1 mm² stripe-shaped devices, such as laser diodes with nonpolar or semipolar large-area surfaces and c-plane facets, could be expected to be free of stacking faults.

In certain embodiments, the light emitting diode, laser diode, or other optoelectronic or electronic device is incorporated into a luminaire, light source, module, or system.

Although the above is a full description of specific embodiments, various modifications, alternative constructions and equivalents may be used. Therefore, the above description and illustrations should not be taken as limiting the scope of the present disclosure which is defined by the appended claims.

1. A free-standing crystal, comprising a group III metal and nitrogen, wherein the free-standing crystal comprises:
a wurtzite crystal structure;
a first surface having a maximum dimension greater than 80 millimeters in a first direction;
an average concentration of stacking faults below 10³ cm⁻¹; and
an average concentration of threading dislocations between 1 cm⁻² and 10⁶ cm⁻²; wherein
at each of five points distributed evenly within a central 80% of an area of the first surface, the free-standing crystal is characterized by a x-ray rocking curve in the first direction having a full-width-at-half-maximum FWHM_{∥} value that is greater than the FWHM_{⊥} value of an x-ray rocking curve measured in a second direction orthogonal to the first direction by a difference corresponding to a difference in crystallographic orientation between about 0.01 degrees and about 0.4 degrees.

2. The free-standing crystal of claim 1, wherein, at each of the five points, an x-ray rocking curve in the first direction is characterized by at least two peaks, with a maximum peak separation corresponding to a difference in crystallographic orientation between about 0.01 degrees and about 0.4 degrees.

3. The free-standing crystal of claim 2, wherein, at each of the five points, an x-ray rocking curve in the first direction is characterized by at least two peaks, with a maximum peak separation corresponding to a difference in crystallographic orientation between about 0.02 degrees and about 0.2 degrees.

4. The free-standing crystal of claim 1, wherein, at each of the five points, an x-ray rocking curve in the second direction is characterized by a single peak.

5. A free-standing crystal, comprising a group III metal and nitrogen, wherein the free-standing crystal comprises:
a wurtzite crystal structure;
a first surface having a maximum dimension greater than 80 millimeters in a first direction;
an average concentration of stacking faults below 10³ cm⁻¹; and
an average concentration of threading dislocations between 1 cm⁻² and 10⁶ cm⁻²; wherein
at each of five points distributed evenly within a central 80% of an area of the first surface, the free-standing crystal is characterized by a x-ray rocking curve in the first direction having a full-width-at-eighth-maximum FWEM_{∥} value that is greater than the FWEM_{⊥} value of an x-ray rocking curve measured in a second direction orthogonal to the first direction by a difference corresponding to a difference in crystallographic orientation between about 0.01 degrees and about 0.4 degrees.

6. The free-standing crystal of claim 5, wherein, at each of the five points, an x-ray rocking curve in the first direction is characterized by a single peak having a full-width-at-eighth-maximum FWEM_{∥} value that is greater than the FWEM_{⊥} value measured in the second direction, by a difference corresponding to a difference in crystallographic orientation between about 0.02 degrees and about 0.1 degrees.

7. The free-standing crystal of claim 1, wherein the first surface of the free-standing crystal further comprises an impurity concentration of H greater than 10¹⁶ cm⁻³, and an impurity concentration of at least one of Li, Na, K, F, Cl, Br, and I greater than 10¹⁵ cm⁻³, as quantified by calibrated secondary ion mass spectrometry.

8. The free-standing crystal of claim 1, wherein the first surface is characterized by impurity concentrations of
oxygen (O) between 1×10¹⁶ cm⁻³ and 1×10¹⁹ cm⁻³;
hydrogen (H) between 1×10¹⁶ cm⁻³ and 2×10¹⁹ cm⁻³; and
at least one of fluorine (F) and chlorine (Cl) between 1×10¹⁵ cm⁻³ and 1×10¹⁹ cm⁻³.

9. The free-standing crystal of claim 1, wherein at each of nine points distributed evenly within a central 80% of an area of the first surface, the free-standing crystal is further characterized by a x-ray rocking curve in the first direction having a full-width-at-half-maximum FWHM_{∥} value that is greater than the FWHM_{⊥} value of an x-ray rocking curve measured in the second direction by a difference corresponding to a difference in crystallographic orientation between about 0.01 degrees and about 0.4 degrees.

10. The free-standing crystal of claim 1, wherein
the first surface comprises a plurality of first regions, each of the plurality of first regions having a locally-approximately-linear array of threading dislocations with a concentration between 5 cm⁻² and 10⁵ cm⁻², and
the first surface further comprises a plurality of second regions, each of the plurality of second regions being disposed between an adjacent pair of the plurality of first regions and having a concentration of threading dislocations below 10⁵ cm⁻² and a concentration of stacking faults below 10³ cm⁻¹.

11. The free-standing crystal of claim 1, wherein the x-ray rocking curves are measured with an illuminated area being limited to being 2 millimeters wide by slits in a diffractometer.

12. A method for forming a composite substrate, comprising:
forming a pattern on a template, the pattern comprising growth centers having a minimum dimension between 1 micrometer and 100 micrometers, and being characterized by at least one pitch dimension between 20 micrometers and 5 millimeters, wherein the template has a diameter in a first direction of at least 25 millimeters and comprises a group III metal nitride layer on a template substrate comprising one of sapphire, silicon carbide, gallium arsenide, silicon, germanium, a silicon-germanium alloy, MgAl₂O₄ spinel, ZnO, ZrB₂, BP, InP, AION, ScAlMgO₄, YFeZnO₄, MgO, Fe₂NiO₄, LiGa₅O₈, Na₂MoO₄, Na₂WO₄, In₂CdO₄, lithium aluminate (LiAlO₂), LiGaO₂, Ca₈La₂(PO₄)₆O₂, gallium nitride (GaN), or aluminum nitride (AlN);
growing a group III metal nitride layer from the pattern of growth centers vertically and laterally such that a lateral gap remains between adjacent laterally growth regions, the lateral gap having a width between about 1 micrometer and about 1 millimeter;
bonding a handle substrate to the group III metal nitride layer, the handle substrate having a coefficient of thermal expansion in the first direction that is within 10% of the coefficient of thermal expansion of the group III metal nitride layer in the first direction, averaged between room temperature and 800 degrees Celsius.

13. The method of claim 12, wherein the group III metal nitride layer comprises a group III metal selected from gallium, aluminum, indium, and a combination of any of the foregoing and nitrogen.

14. The method of claim 12, wherein the template substrate comprises sapphire or silicon.

15. The method of claim 12, wherein handle substrate comprises polycrystalline group III metal nitride.

16. The method of claim 15, wherein the handle substrate is characterized by a pole figure having a (0002) reflection at an angle within 5 degrees of a normal to its surface and where the full-width-at-half-maximum (FWHM) of the (0002) reflection in a χ- (or α-)scan is less than or equal to 10 degrees.

17. The method of claim 12, wherein
the handle substrate is bonded to the group III metal nitride layer by means of at least one bonding layer having a nascent melting point below 500 degrees Celsius, and
the method further comprises thermally treating the bonding layer to cause the melting point of the bonding layer to increase to a temperature of above 600 degrees.

18. The method of claim 12, wherein the handle substrate is bonded to the group III metal nitride layer by depositing a polycrystalline group III metal nitride layer over the group III metal nitride layer.

19. The method of claim 12, further comprising a bulk crystal growth process, using the composite substrate as a seed crystal, and forming a free-standing group III metal nitride boule.

20. The method of claim 19, further comprising preparing one or more free-standing group III metal nitride wafers from the free-standing group III metal nitride boule.
